(19) United States
(12) Patent Application Publication
(10) Pub. No.: US 2026/0371735 A1
(43) Pub. Date: Nov. 19, 2026

(54) DISPLAY DEVICE, ELECTRONIC DEVICE USING THE DISPLAY DEVICE, AND METHOD OF FABRICATING THE DISPLAY DEVICE

(71) Applicant: Samsung Display Co., Ltd., Yongin-Si (KR)

(72) Inventors: Keun Woo KIM, Yongin-si (KR); Hyun Eok SHIN, Yongin-si (KR); Joon Yong PARK, Yongin-si (KR); Yun Jong YEO, Yongin-si (KR)

(21) Appl. No.: 19/454,402

(22) Filed: Jan. 21, 2026

(30) Foreign Application Priority Data
May 16, 2025 (KR) 10-2025-0063587

(51) Int. Cl. H10D 86/40; H10D 86/01; H10D 86/60; H10K 59/12; H10K 59/123; H10K 59/124; H10H 29/01; H10H 29/39; H10H 29/41

(52) U.S. Cl. CPC H10D 86/451; H10D 86/0231; H10D 86/441; H10D 86/60; H10K 59/1201; H10K 59/123; H10K 59/124; H10H 29/012; H10H 29/39; H10H 29/41

(57) ABSTRACT

There is provided a display device. The display device a display device includes a substrate comprising a semiconductor layer; a first insulating layer located on the semiconductor layer; a first contact hole comprising an opening which extends through the first insulating layer to the semiconductor layer; a conductive layer located on the first insulating layer and contacting the semiconductor layer in a portion overlapping the first contact hole; and a first auxiliary insulating layer located between the first insulating layer and the conductive layer and defining an insulating opening. The insulating opening overlaps the first contact hole, a width of the insulating opening is smaller than a width of the first contact hole, and a thickness of the first auxiliary insulating layer decreases in a direction toward the semiconductor layer in the portion overlapping the first contact hole.

This application claims the benefit of Korean Patent Application No. 10-2025-0063587, filed on May 16, 2025, in the Korean Intellectual Property Office, the disclosure of which is incorporated herein in its entirety by reference.

### BACKGROUND

### FIELD

The present disclosure relates to a display device, an electronic device using the display device, and a method of fabricating the display device.

### DESCRIPTION OF THE RELATED ART

As the information society develops, demands for display devices for displaying images are increasing in various forms. For example, display devices are applied to various electronic devices such as smartphones, digital cameras, notebook computers, navigation devices, and smart televisions. The display devices may be flat panel display devices such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit that provides light to the display panel.

With a recent increase in high-resolution display devices, semiconductor layers and conductive layers included in a display device may be arranged and spaced apart within a narrow area. Therefore, the semiconductor layers and the conductive layers may be stacked vertically with inorganic insulating layers located between the semiconductor layers and the conductive layers. Accordingly, a plurality of contact holes included in a high-resolution display device may be required to have a narrow width within a certain range.

### SUMMARY

An aspect of the present disclosure is to provide a display device capable of providing a high-resolution image and a method of fabricating the display device.

Another aspect of the present disclosure is to form a plurality of contact holes included in a thin-film transistor layer to include a contact opening of 0.8 micrometers or less.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to one or more embodiments of the disclosure, a display device includes a substrate comprising a semiconductor layer; a first insulating layer located on the semiconductor layer; a first contact hole comprising an opening which extends through the first insulating layer to the semiconductor layer; a conductive layer located on the first insulating layer and contacting the semiconductor layer in a portion overlapping the first contact hole; and a first auxiliary insulating layer located between the first insulating layer and the conductive layer and defining an insulating opening. The insulating opening overlaps the first contact hole, a width of the insulating opening is smaller than a width of the first contact hole, and a thickness of the first auxiliary insulating layer decreases in a direction toward the semiconductor layer in the portion overlapping the first contact hole.

In an embodiment, the insulating opening may comprise a contact opening, and the semiconductor layer and the conductive layer contact each other in a portion overlapping the contact opening.

In an embodiment, a width of the contact opening may be 0.8 micrometers or less.

In an embodiment, the first contact hole may completely surround the insulating opening, and the width of the first contact hole ranges from 1.0 micrometer to 1.5 micrometers.

In an embodiment, the first auxiliary insulating layer comprises a first portion in contact with an upper surface of the first insulating layer and a second portion in contact with a side surface of the first insulating layer, and a thickness of the first portion is greater than a thickness of the second portion.

In an embodiment, the display device may further comprise gate insulating layers located between the semiconductor layer and the first insulating layer. The first auxiliary insulating layer further comprises a third portion in contact with a side surface of at least any one of the gate insulating layers, and the thickness of the second portion of the first auxiliary insulating layer is greater than a thickness of the third portion.

In an embodiment, the first auxiliary insulating layer may further comprise a fourth portion overlapping the contact opening in a direction parallel to a surface of the substrate, and a thickness of the fourth portion is smaller than the thicknesses of the first portion, the second portion and the third portion.

In an embodiment, the conductive layer may cover the upper and side surfaces of the first insulating layer and is spaced apart from the upper and side surfaces of the first insulating layer by the first auxiliary insulating layer located between the conductive layer and the upper and side surfaces of the first insulating layer.

In an embodiment, the first contact hole may have a reverse-tapered shape, and the first insulating layer facing the first contact hole has a tapered shape.

In an embodiment, an inclination angle formed by a side surface of the first insulating layer which faces the first contact hole and a surface of the substrate may be 80 degrees or less.

In an embodiment, the first auxiliary insulating layer may comprise at least any one of silicon nitride and silicon oxynitride.

In an embodiment, the thickness of the first auxiliary insulating layer may be smaller than a thickness of the first insulating layer.

In an embodiment, the display device may further comprise a second insulating layer located on the conductive layer a second contact hole extending through the second insulating layer to the conductive layer; a source-drain layer located on the second insulating layer; and a second auxiliary insulating layer located between the second insulating layer and the source-drain layer and defining an insulating opening. The insulating opening of the second auxiliary insulating layer overlaps the second contact hole, a width of the insulating opening of the second auxiliary insulating layer is smaller than a width of the second contact hole, and the conductive layer and the source-drain layer contact each other in a portion overlapping the insulating opening of the second auxiliary insulating layer.

According to one or more embodiments of the disclosure, a method of fabricating a display device, the method includes forming a contact hole which penetrates a plurality of insulating layers; forming an auxiliary insulating layer which overlaps the contact hole and then forming an insulating opening of the auxiliary insulating layer; and forming a conductive pattern on the auxiliary insulating layer. The insulating opening is formed in a portion overlapping the contact hole by performing a dry etching process, a width of the insulating

opening is smaller than a width of the contact hole, and the contact hole completely surrounds the insulating opening.

In an embodiment, the auxiliary insulating layer may be formed by a sputtering method, and a thickness of the auxiliary insulating layer decreases as a depth of the contact hole increases.

According to one or more embodiments of the disclosure, an electronic device comprising: at least one display device comprising a substrate which comprises a semiconductor layer; and at least any one of a display module, one or more processors, a memory, or a power module connected to the display device. The at least one display device comprises: a first insulating layer located on the semiconductor layer; a first contact hole extending through the first insulating layer to the semiconductor layer; a conductive layer located on the first insulating layer and contacting the semiconductor layer in a portion overlapping the first contact hole; and a first auxiliary insulating layer located between the first insulating layer and the conductive layer and defining an insulating opening. The insulating opening overlaps the first contact hole, a width of the insulating opening is smaller than a width of the first contact hole, and a thickness of the first auxiliary insulating layer decreases in a direction toward the semiconductor layer in the portion overlapping the first contact hole.

According to a display device according to embodiments, an electronic device using the display device, and a method of fabricating the display device, a high-resolution image can be provided, and a plurality of contact holes included in a thin-film transistor layer can include a contact opening of 0.8 micrometers or less.

However, the effects of the present disclosure are not restricted to the one set forth herein. The above and other effects of the present disclosure will become more apparent to one of daily skill in the art to which the present disclosure pertains by referencing the detailed description of the present disclosure given below.

### BRIEF DESCRIPTION OF THE DRAWINGS

These and/or other aspects will become apparent and more readily appreciated from the following description of the embodiments, taken in conjunction with the accompanying drawings.

FIG. 1 is a perspective view of a head-mounted electronic device according to an embodiment.

FIG. 2 is an exploded perspective view of an example of the head-mounted electronic device of FIG. 1.

FIG. 3 is a perspective view of a head-mounted electronic device according to an embodiment.

FIG. 4 is a perspective view of a display device according to an embodiment.

FIG. 5 is a cross-sectional view of the display device according to the embodiment.

FIG. 6 is a plan view of a display layer of the display device according to the embodiment.

FIG. 7 is a cross-sectional view of an example of the display layer taken along line X-X’ of FIG. 6.

FIG. 8 is an enlarged cross-sectional view of area ‘A’ in FIG. 7.

FIG. 9 is an enlarged cross-sectional view of area ‘A’ in FIG. 7 according to a comparative example.

FIG. 10 is an enlarged cross-sectional view of area ‘C’ in FIG. 7.

FIG. 11 is a flowchart illustrating a process of fabricating a plurality of insulating layers, a first auxiliary insulating layer, and a first conductive pattern which overlap a first contact hole in FIG. 8.

FIGS. 12 and 13 are cross-sectional views illustrating an operation S100 of FIG. 11.

FIGS. 14, 15, and 16 are cross-sectional views illustrating an operation S200 of FIG. 11.

FIG. 17 is a cross-sectional view illustrating an operation S300 of FIG. 11.

FIG. 18 is a block diagram of an electronic device according to an embodiment.

FIG. 19 is a schematic diagram of electronic devices according to various embodiments.

### DETAILED DESCRIPTION

The inventive concept will now be described more fully herein with reference to the accompanying drawings, in which some embodiments of the inventive concept are shown. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It is also to be understood that when a layer is referred to as being "on" another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements should not be limited by these terms. These terms are used to distinguish one element from another element. For instance, a first element discussed below could be termed a second element without departing from the teachings of the inventive concept. Similarly, the second element could also be termed a first element.

Unless otherwise defined, all terms (including technical and scientific terms) used herein have the same meaning as commonly understood by one of ordinary skill in the art to which the inventive concept pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, embodiments of the present disclosure will be described in detail with reference to the accompanying drawings.

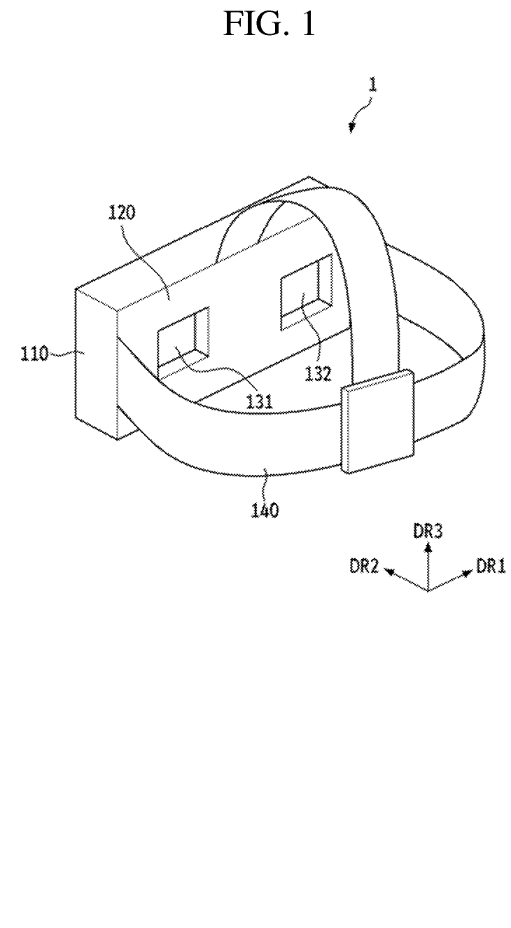

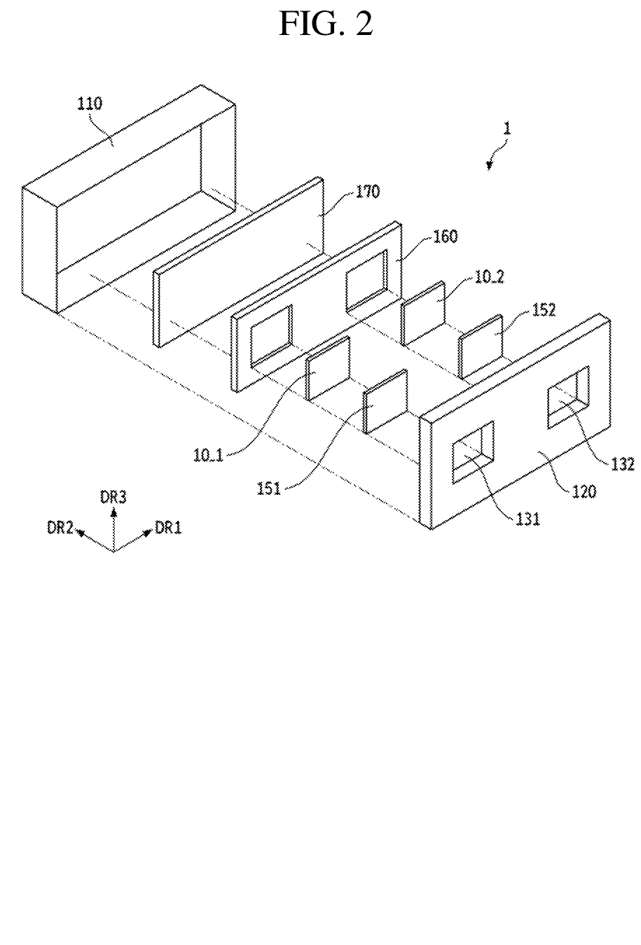

FIG. 1 is a perspective view of a head-mounted electronic device 1 according to an embodiment. FIG. 2 is an exploded perspective view of an example of the head-mounted electronic device 1 of FIG. 1.

Referring to FIGS. 1 and 2, the head-mounted electronic device 1 according to the embodiment includes a display device housing 110, a housing cover 120, a first eyepiece 131, a second eyepiece 132, a head-mounted band 140, a first display device 10_1, a second display device 10_2, a middle frame 160, a first optical member 151, a second optical member 152, a control circuit board 170, and a connector.

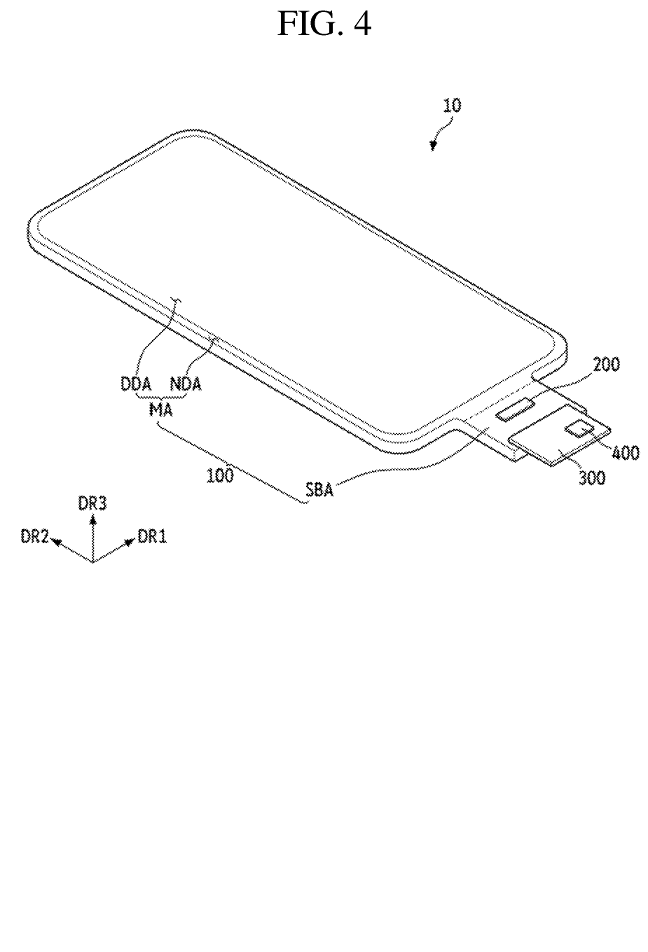

The first display device 10_1 provides an image to a user’s left eye, and the second display device 10_2 provides an image to the user’s right eye. Each of the first display device 10_1 and the second display device 10_2 is substantially the same as a display device 10 to be described with reference to FIG. 4. Therefore, a description of the first display device 10_1 and the second display device 10_2 is replaced with descriptions given with reference to FIG. 4.

The first optical member 151 may be located between the first display device 10_1 and the first eyepiece 131. The second optical member 152 may be located between the second display device 10_2 and the second eyepiece 132. Each of the first optical member 151 and the second optical member 152 may include at least one convex lens.

The middle frame 160 may be located between the first display device 10_1 and the control circuit board 170 and may be located between the second display device 10_2 and the control circuit board 170. The middle frame 160 supports and fixes the first display device 10_1, the second display device 10_2, and the control circuit board 170.

The control circuit board 170 may be located between the middle frame 160 and the display device housing 110. The control circuit board 170 may be connected to the first display device 10_1 and the second display device 10_2 through a connector. The control circuit board 170 may convert an image source received from the outside into digital video data and transmit the digital video data to the first display device 10_1 and the second display device 10_2 through the connector.

The control circuit board 170 may transmit digital video data corresponding to a left image optimized for a user’s left eye to the first display device 10_1 and transmit digital video data corresponding to a right image optimized for the user’s right eye to the second display device 10_2. In an embodiment, the control circuit board 170 may transmit the same digital video data to the first display device 10_1 and the second display device 10_2.

The display device housing 110 houses the first display device 10_1, the second display device 10_2, the middle frame 160, the first optical member 151, the second optical member 152, the control circuit board 170, and the connector. The housing cover 120 is placed to cover an open surface of the display device housing 110. The housing cover 120 may include the first eyepiece 131 on which a user’s left eye is placed and the second eyepiece 132 on which the user’s right eye is placed. Although the first eyepiece 131 and the second eyepiece 132 are located separately in FIGS. 1 and 2, embodiments of the present specification are not limited to this case. The first eyepiece 131 and the second eyepiece 132 may also be combined into one.

The first eyepiece 131 may be aligned with the first display device 10_1 and the first optical member 151, and the second eyepiece 132 may be aligned with the second display device 10_2 and the second optical member 152. Therefore, a user can view an image of the first display device 10_1, which is enlarged as a virtual image by the first optical member 151, through the first eyepiece 131 and can view an image of the second display device 10_2, which is enlarged as a virtual image by the second optical member 152, through the second eyepiece 132.

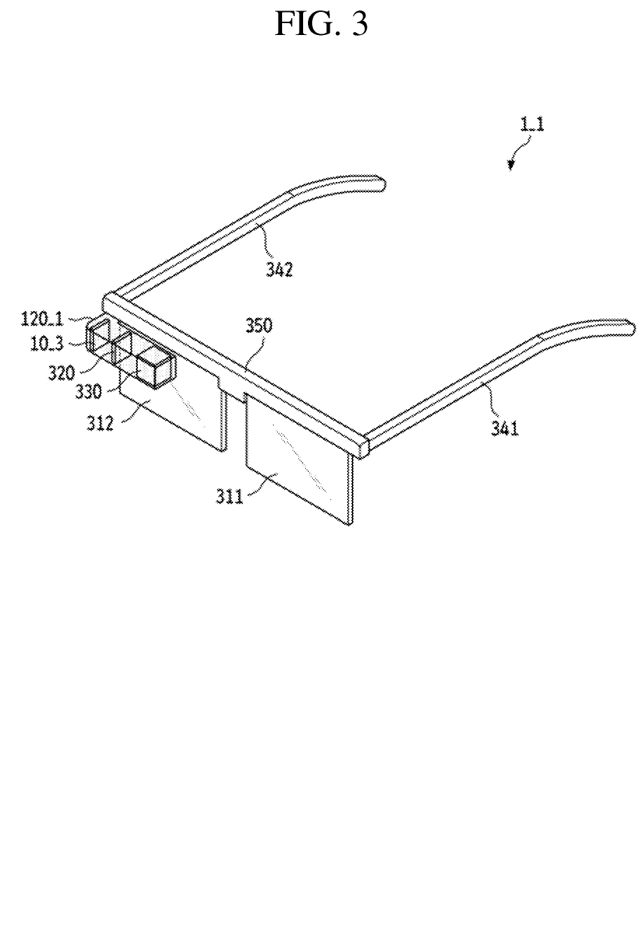

The head-mounted band 140 fixes the display device housing 110 to a user’s head so that the first eyepiece 131 and the second eyepiece 132 of the housing cover 120 are kept placed on the user’s left and right eyes, respectively. When the display device housing 110 is implemented to be lightweight and small, the head-mounted electronic device 1 may include an eyeglass frame as illustrated in FIG. 3 instead of the head-mounted band 140.

In addition, the head-mounted electronic device 1 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 3 is a perspective view of a head-mounted electronic device 1_1 according to an embodiment.

Referring to FIG. 3, the head-mounted electronic device 1_1 according to the embodiment may be a display device in the form of glasses in which a display device housing 120_1 is implemented to be lightweight and small. The head-mounted electronic device 1_1 according to the embodiment may include a display device 10_3, a left lens 311, a right lens 312, a support frame 350, eyeglass frame legs 341 and 342, an optical member 320, an optical path conversion member 330, and the display device housing 120_1.

The display device 10_3 illustrated in FIG. 3 is substantially the same as the display device 10 to be described with reference to FIG. 4.

The display device housing 120_1 may include the display device 10_3, the optical member 320, and the optical path conversion member 330. An image displayed on the display device 10_3 may be enlarged by the optical member 320, may have its optical path converted by the optical path conversion member 330, and then may be provided to a user’s right eye through the right lens 312. Accordingly, the user can view, through the right eye, an augmented reality image into which a virtual image displayed on the display device 10_3 and a real image viewed through the right lens 312 are combined.

Although the display device housing 120_1 is located at a right end of the support frame 350 in FIG. 3, embodiments of the present specification are not limited to this case. For example, the display device housing 120_1 may also be located at a left end of the support frame 350. In this case, an image of the display device 10_3 may be provided to a user’s left

eye. In an embodiment, the display device housing 120_1 may be located at both the left and right ends of the support frame 350. In this case, the user can view an image displayed on the display device 10_3 through both the left and right eyes.

FIG. 4 is a perspective view of a display device 10 according to an embodiment.

Referring to FIG. 4, the display device 10 may be applied to portable electronic devices such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. For another example, the display device 10 may be applied to wearable devices such as smart watches, watch phones, glasses-type displays, and head-mounted displays.

The display device 10 may have a planar shape similar to a quadrangle. For example, the display device 10 may have a planar shape similar to a quadrangle having short sides in a first direction DR1 and long sides in a second direction DR2. Each corner where a short side extending in the first direction DR1 meets a long side extending in the second direction DR2 may be rounded to have a selected curvature or may be right-angled. The planar shape of the display device 10 is not limited to a quadrangular shape but may also be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA. The main area MA may include a display area DDA including pixels that display an image and a non-display area NDA located around the display area DDA.

The display area DDA may emit light from a plurality of emission areas or a plurality of openings which will be described later. For example, the display panel 100 may include a pixel circuit including switching elements, a pixel defining layer defining an emission area or an opening, and a self-light emitting element. For example, the self-light emitting element may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode. The drawings below illustrate a case where the self-light emitting element is an organic light emitting diode.

The non-display area NDA may be an area outside the display area DDA. The non-display area NDA may be defined as an edge area of the main area MA of the display panel 100.

The sub-area SBA may extend from a side of the main area MA. The sub-area SBA may include a flexible material that can be bent, folded, rolled, etc. For example, when the sub-area SBA is bent, it may be overlapped by the main area MA in a thickness direction (e.g., a third direction DR3). The sub-area SBA may include the display driver 200 and a pad unit connected to the circuit board 300. In an embodiment, the sub-area SBA may be omitted, and the display driver 200 and the pad unit may be located in the non-display area NDA.

The display driver 200 may output signals and voltages for driving the display panel 100. The display driver 200 may be formed as an integrated circuit and mounted on the display panel 100 by a chip on glass (COG) method, a chip on plastic (COP) method, or an ultrasonic bonding method. For example, the display driver 200 may be located in the sub-area SBA and may be overlapped by the main area MA in the thickness direction by the bending of the sub-area SBA. For another example, the display driver 200 may be mounted on the circuit board 300.

The circuit board 300 may be attached onto the pad unit of the display panel 100 using an anisotropic conductive film. The circuit board 300 may be a flexible printed circuit board, a printed circuit board, or a flexible film such as a chip on film.

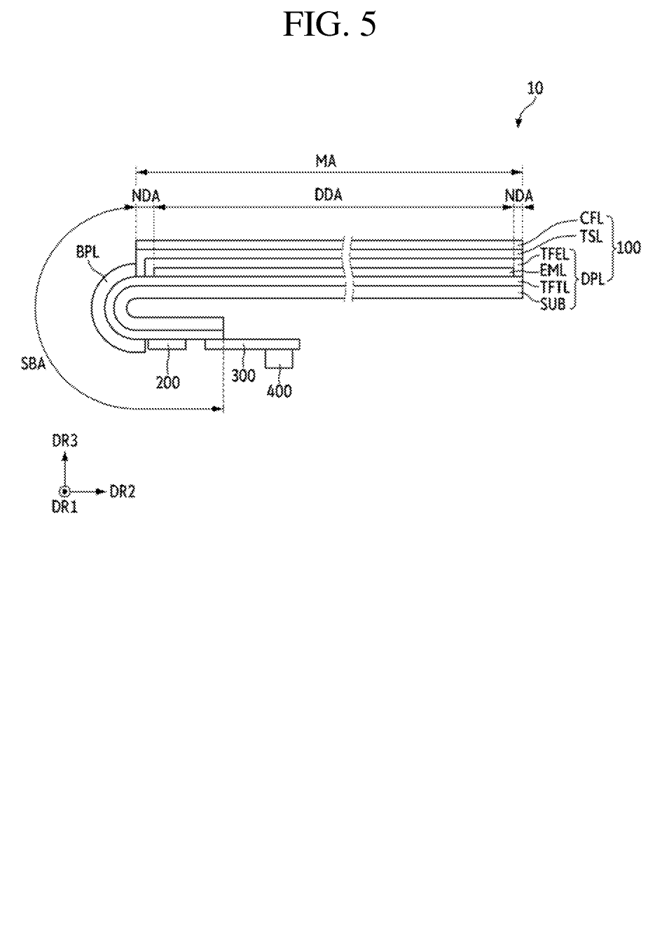

The touch driver 400 may be mounted on the circuit board 300. The touch driver 400 may be connected to a touch sensor layer TSL (see FIG. 5) for sensing and driving a touch on the display device 10.

FIG. 5 is a cross-sectional view of the display device 10 according to the embodiment.

Referring to FIG. 5, the display panel 100 may include a display layer DPL, the touch sensor layer TSL, and a color filter layer CFL. The display layer DPL may include a substrate SUB, a transistor layer TFTL, a display element layer EML, and an encapsulation layer TFEL.

The substrate SUB may be a base substrate or a base member. The substrate SUB may be a flexible substrate that can be bent, folded, rolled, etc. For example, the substrate SUB may include polymer resin such as polyimide (PI). However, the material of the substrate SUB is not limited to polymer resin. In an embodiment, the substrate SUB may include a glass material or a metal material.

The transistor layer TFTL may be located on the substrate SUB. The transistor layer TFTL may be located in portions overlapping the display area DDA, the non-display area NDA, and the sub-area SBA.

The display element layer EML may be located on the transistor layer TFTL. The display element layer EML may be located in the portion overlapping the display area DDA. The display element layer EML may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode.

The encapsulation layer TFEL may be located on the display element layer EML. The encapsulation layer TFEL may be located in the portions overlapping the display area DDA and the non-display area NDA. The encapsulation layer TFEL may cover upper and side surfaces of the display element layer EML and may protect the display element layer EML from external oxygen and moisture. The encapsulation layer TFEL may include at least one inorganic layer and at least one organic layer to encapsulate the display element layer EML.

The touch sensor layer TSL may be located on the encapsulation layer TFEL. The touch sensor layer TSL may be located in the portions overlapping the display area DDA and the non-display area NDA. The touch sensor layer TSL may sense a user’s touch in a mutual capacitance manner or a self-capacitance manner. The touch sensor layer TSL can be omitted depending on embodiments.

The color filter layer CFL may be located on the touch sensor layer TSL. The color filter layer CFL may be located in the portions overlapping the display area DDA and the non-display area NDA. The color filter layer CFL may absorb a part of light coming from the outside of the display device 10, thereby reducing reflected light caused by the external light. Therefore, the color filter layer CFL can prevent color distortion caused by reflection of external light.

Since the color filter layer CFL is directly located on the touch sensor layer TSL, the display device 10 may not require a separate substrate for the color filter layer CFL. Therefore, a thickness of the display device 10 may be relatively small. The color filter layer CFL can be omitted depending on embodiments.

As illustrated in FIG. 5, a portion of the display panel 100 which overlaps the sub-area SBA may be bent. When the portion of the display panel 100 is bent, the display driver 200, the circuit board 300, and the touch driver 400 may be overlapped by the main area MA in the third direction DR3.

When the portion of the display panel 100 is bent, a bending protection layer BPL may protect a structure located under the bending protection layer BPL and overlapping the sub-area SBA from bending stress.

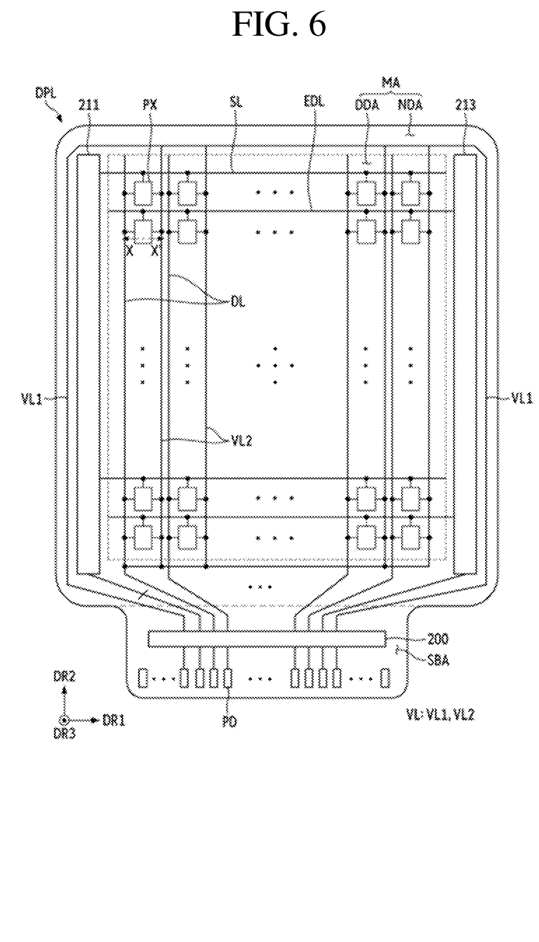

FIG. 6 is a plan view of the display layer DPL of the display device 10 according to the embodiment.

Referring to FIG. 6, the display layer DPL may include a plurality of pixels PX and a plurality of power lines VL, a plurality of scan lines SL, a plurality of emission control lines EDL and a plurality of data lines DL connected to the pixels PX in a portion overlapping the display area DDA.

The scan lines SL may extend in the first direction DR1 and may be spaced apart from each other in the second direction DR2 intersecting the first direction DR1. The scan lines SL may be arranged along the second direction DR2. The scan lines SL may sequentially supply scan signals to the pixels PX.

The emission control lines EDL may extend in the first direction DR1 and may be spaced apart from each other in the second direction DR2. The emission control lines EDL may be arranged along the second direction DR2. The emission control lines EDL may sequentially supply emission signals to the pixels PX.

The data lines DL may extend in the second direction DR2 and may be spaced apart from each other in the first direction DR1. The data lines DL may be arranged along the first direction DR1. The data lines DL may supply data voltages to the pixels PX. The data voltages may determine respective luminance of the pixels PX.

The power lines VL may include a main power line VL1 and sub-power lines VL2. At least any one of a first power supply voltage (high potential voltage) and a second power supply voltage (low potential voltage) may be transmitted to the sub-power lines VL2 through the main power line VL1 overlapping the non-display area NDA. The main power line VL1 and the sub-power lines VL2 may be collectively referred to as the power lines VL.

The non-display area NDA may surround the display area DDA. The non-display area NDA may include a scan driver 211 and an emission control driver 213.

The scan driver 211 may be located outside one side of the display area DDA or on one side of the non-display area NDA. The scan driver 211 may include a plurality of driving transistors which generate gate signals based on a gate control signal.

The emission control driver 213 may be located outside another side of the display area DDA or on another side of the non-display area NDA. The emission control driver 213 may include a plurality of emission control transistors which generate emission signals based on an emission control signal.

The display layer DPL included in an embodiment may include the display driver 200 and a plurality of pad electrodes PD in a portion overlapping the sub-area SBA. The pad electrodes PD may be spaced apart from each other in the first direction DR1 and may be connected to different lines, respectively.

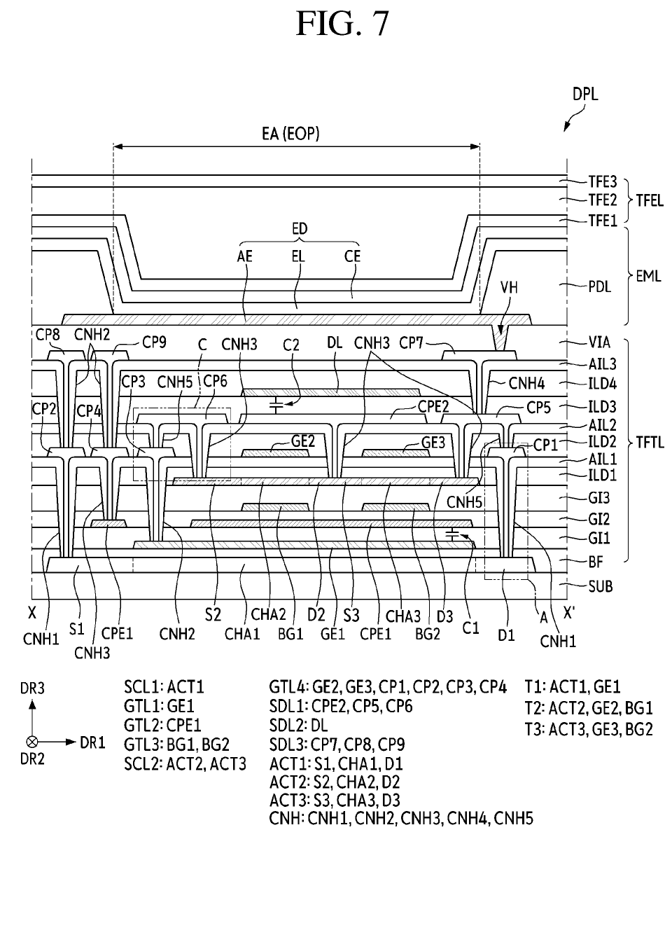

FIG. 7 is a cross-sectional view of an example of the display layer DPL taken along line X-X’ of FIG. 6. FIG. 7 illustrates a schematic cross-sectional view of the substrate SUB, the transistor layer TFTL, the display element layer EML, and the encapsulation layer TFEL included in the display layer DPL.

Referring to FIG. 7 in addition to FIGS. 1-6, the transistor layer TFTL may be located on the substrate SUB. The transistor layer TFTL may include a plurality of semiconductor layers, a plurality of conductive layers, and a plurality of insulating layers.

Since the display device 10 of the embodiment is applied to a high-resolution electronic device 1, the semiconductor layers and/or the conductive layers included in the transistor layer TFTL may be placed within a narrow area. Therefore, the semiconductor layers and/or the conductive layers of an embodiment may be stacked in the third direction DR3 with the insulating layers. The insulating layers may be located between the semiconductor layers and/or the conductive layers.

The transistor layer TFTL of an embodiment may include a first semiconductor layer SCL1, a buffer layer BF, a first conductive layer GTL1, a first gate insulating layer GI1, a second conductive layer GTL2, a second gate insulating layer GI2, a third conductive layer GTL3, a third gate insulating layer GI3, a second semiconductor layer SCL2, a first insulating layer ILD1, a fourth conductive layer GTL4, a second insulating layer ILD2, a first source-drain layer SDL1, a third insulating layer ILD3, a second source-drain layer SDL2, a fourth insulating layer ILD4, a third source-drain layer SDL3, and a via layer VIA.

The first semiconductor layer SCL1 may be located on the substrate SUB. The first semiconductor layer SCL1 may include a first active layer ACT1 included in a first transistor T1 of a pixel PX. For example, the first transistor T1 may be a driving transistor.

The first active layer ACT1 may include a first channel region CHA1, a first source region S1, and a first drain region D1. The first channel region CHA1 may overlap a first gate electrode GE1 in the third direction DR3. The first channel region CHA1 may form a channel in response to a voltage applied to the first gate electrode GE1.

The first source region S1 and the first drain region D1 may be located on opposite sides of the first channel region CHA1. The first source region S1 and the first drain region D1 may have higher conductivity than the first channel region CHA1. For example, the carrier concentration of the first source region S1 and the first drain region D1 may be higher than the carrier concentration of the first channel region CHA1.

Since the display device 10 of the embodiment is applied to a high-resolution electronic device as described above, a length of a channel region may have a value within a certain range. For example, a length of the first channel region CHA1 may range from 1.0 micrometer to 3.0 micrometers. In addition, a length of each of the first drain region D1 and the first source region S1 may range from 1.0 micrometer to 1.5 micrometers.

The buffer layer BF may be located on the substrate SUB and the first semiconductor layer SCL1. The buffer layer BF may cover the entire first semiconductor layer SCL1.

The buffer layer BF may include an inorganic insulating material. For example, the buffer layer BF may include silicon nitride (e.g., Si₃N₄ or SiNₓ), silicon oxide (e.g., SiO₂ or SiOₓ), silicon oxynitride (e.g., SiON), titanium oxide, aluminum oxide, or other inorganic insulating materials.

The first conductive layer GTL1 may be located on the buffer layer BF. The first conductive layer GTL1 may include a conductive material. For example, the first conductive layer GTL1 may include at least one of molybdenum (Mo), aluminum (Al), chromium (Cr), gold (Au), silver (Ag), titanium (Ti), nickel (Ni), neodymium (Nd), copper (Cu) and other metals, an alloy thereof, or other conductive materials.

The first conductive layer GTL1 may include the first gate electrode GE1 included in the first transistor T1 of the pixel PX.

The first gate electrode GE1 may overlap the first channel region CHA1 of the first active layer ACT1 and a first capacitor electrode CPE1 in the third direction DR3. The first gate electrode GE1 may be located between the first channel region CHA1 and the first capacitor electrode CPE1.

The first gate insulating layer GI1 may be located on the buffer layer BF and the first conductive layer GTL1. The first gate insulating layer GI1 may cover the entire first conductive layer GTL1.

The first gate insulating layer GI1 may include an inorganic insulating material. Examples of the inorganic insulating material are omitted.

The second conductive layer GTL2 may be located on the first gate insulating layer GI1. The second conductive layer GTL2 may include a conductive material. Examples of the conductive material are omitted below.

The second conductive layer GTL2 may include the first capacitor electrode CPE1. The first capacitor electrode CPE1 is illustrated as being separated into two conductive patterns. However, the first capacitor electrode CPE1 may be connected as one in plan view.

A capacitor C1 may be formed between the first gate electrode GE1 and the first capacitor electrode CPE1. The first gate electrode GE1 and the first capacitor electrode CPE1 may form a first electrode and a second electrode of the capacitor C1, respectively.

The second gate insulating layer GI2 may be located on the first gate insulating layer GI1 and the second conductive layer GTL2. The second gate insulating layer GI2 may cover the entire second conductive layer GTL2.

The second gate insulating layer GI2 may include an inorganic insulating material. Examples of the inorganic insulating material are omitted below.

The third conductive layer GTL3 may be located on the second gate insulating layer GI2. The third conductive layer GTL3 may include a conductive material.

The third conductive layer GTL3 may include a first bottom electrode BG1 and a second bottom electrode BG2. The first bottom electrode BG1 may overlap a second active layer ACT2 included in a second transistor T2 in the third direction DR3, and the second bottom electrode BG2 may overlap a third active layer ACT3 included in a third transistor T3 in the third direction DR3.

The third gate insulating layer GI3 may be located on the second gate insulating layer GI2 and the third conductive layer GTL3. The third gate insulating layer GI3 may cover the entire third conductive layer GTL3. The third gate insulating layer GI3 may include an inorganic insulating material.

The second semiconductor layer SCL2 may be located on the third gate insulating layer GI3. The second semiconductor layer SCL2 may include the second active layer ACT2 included in the second transistor T2 and the third active layer ACT3 included in the third transistor T3.

The second semiconductor layer SCL2 may include a semiconductor material (e.g., polysilicon, amorphous silicon, an oxide semiconductor, or other semiconductor materials).

The second active layer ACT2 may include a second channel region CHA2, a second source region S2, and a second drain region D2. The second channel region CHA2 may overlap a second gate electrode GE2 included in the second transistor T2 in the third direction DR3. The second channel region CHA2 may form a channel in response to a voltage applied to the second gate electrode GE2. The second source region S2 and the second drain region D2 may be located on opposite sides of the second channel region CHA2. The second source region S2 and the second drain region D2 may have higher conductivity than the second channel region CHA2.

The third active layer ACT3 may include a third channel region CHA3, a third source region S3, and a third drain region D3. The third channel region CHA3 may overlap a third gate electrode GE3 included in the third transistor T3 in the third direction DR3. The third channel region CHA3 may form a channel in response to a voltage applied to the third gate electrode GE3. The third source region S3 and the third drain region D3 may be located on opposite sides of the third channel region CHA3. The third source region S3 and the third drain region D3 may have higher conductivity than the third channel region CHA3.

In an embodiment, the second active layer ACT2 and the third active layer ACT3 may be integrally formed with each other. For example, the second drain region D2 of the second active layer ACT2 and the third source region S3 of the third active layer ACT3 may be integrally formed as one region.

In an embodiment, the second source region S2 may be electrically connected to the first gate electrode GE1 through a sixth conductive pattern CP6 and a third conductive pattern CP3. In addition, the third drain region D3 may be electrically connected to the first drain region D1 through a fifth conductive pattern CP5 and a first conductive pattern CP1. In addition, the second drain region D2 and the third source region S3 may be electrically connected to a second capacitor electrode CPE2.

The first insulating layer ILD1 may be located on the third gate insulating layer GI3 and the second semiconductor layer SCL2. The first insulating layer ILD1 may cover the entire second semiconductor layer SCL2. The first insulating layer ILD1 may include an inorganic insulating material.

A first auxiliary insulating layer AIL1 may be located on the first insulating layer ILD1. The first auxiliary insulating layer AIL1 may cover the entire first insulating layer ILD1.

The first auxiliary insulating layer AIL1 may include an inorganic insulating material. For example, the first auxiliary insulating layer AIL1 may include at least any one of silicon nitride (e.g., Si₃N₄ or SiNₓ) and silicon oxynitride (e.g., SiON).

The fourth conductive layer GTL4 may be located on the first auxiliary insulating layer AIL1. The fourth conductive layer GTL4 may include a conductive material. Examples of the conductive material are omitted.

In an embodiment, the fourth conductive layer GTL4 may include the first conductive pattern CP1, a second conductive pattern CP2, the third conductive pattern CP3, a fourth conductive pattern CP4, the second gate electrode GE2, and the third gate electrode GE3.

The transistor layer TFTL may include a plurality of contact holes CNH. The contact holes CNH may be formed to penetrate, e.g., extend entirely through, a plurality of inorganic insulating layers. The semiconductor layers and the conductive layers included in the transistor layer TFTL may contact each other in portions overlapping openings of the contact holes CNH. Each of the contact holes CNH may have a depth corresponding to a thickness of the insulating layers.

Since display devices applied to ultra-high-resolution electronic devices of 1500 ppi or higher are required recently, the semiconductor layers and the conductive layers may be arranged and spaced apart within a narrow area. Therefore, a width of the openings of the contact holes CNH through which the semiconductor layers and the conductive layers are connected is required to have a value within a certain range. For example, the width of the openings where the semiconductor layers and the conductive layers contact each other may be required to be 0.8 micrometers or less.

In general, the openings of the contact holes CNH may be formed by a photolithography process. However, there may be a process limitation in implementing the width of the contact holes CNH within a certain range (e.g., 1.0 micrometer or less) with the photolithography process. For example, the width of the contact holes CNH formed by the photolithography process may have a value of 1.0 micrometer or more.

Accordingly, the display device 10 of the embodiment proposes a structure in which the openings where the semiconductor layers and the conductive layers contact each other have a width within a certain range (e.g., 0.8 micrometers or less). This structure may be implemented by forming an auxiliary insulating layer covering sidewalls of the contact holes CNH after forming the contact holes CNH.

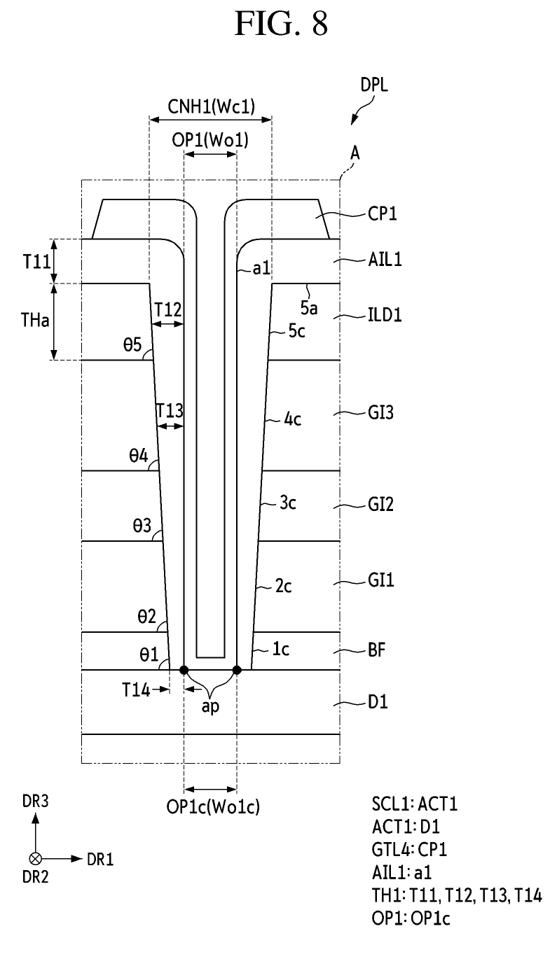

FIG. 8 is an enlarged cross-sectional view of area ‘A’ in FIG. 7.

Referring to FIGS. 7 and 8, a first contact hole CNH1 may penetrate a plurality of inorganic insulating layers. The first contact hole CNH1 of an embodiment may penetrate five inorganic insulating layers. For example, the first contact hole CNH1 may penetrate the buffer layer BF, the first gate insulating layer GI1, the second gate insulating layer GI2, the third gate insulating layer GI3, and the first insulating layer ILD1.

The first contact hole CNH1 may include an opening and may extend to and expose a portion of the first semiconductor layer SCL1 in a portion overlapping the opening. The opening of the first contact hole CNH1 may be described as the first contact hole CNH1 below.

As described above, the first contact hole CNH1 may be formed by a photolithography process in a process of fabricating the display device 10.

In an embodiment, a width Wc1 of the first contact hole CNH1 may range from 1.0 micrometer to 1.5 micrometers.

The first conductive pattern CP1 included in the fourth conductive layer GTL4 may be connected to the first drain region D1 of the first semiconductor layer SCL1 in a portion overlapping the first contact hole CNH1. The second conductive pattern CP2 included in the fourth conductive layer GTL4 may be connected to the first source region S1 of the first semiconductor layer SCL1 through another first contact hole CNH1.

In an embodiment, the first contact hole CNH1 may have a reverse-tapered shape. That is, the width Wc1 of the first contact hole CNH1 may decrease as a depth of the first contact hole CNH1 increases. In other words, the width Wc1 of the first contact hole CNH1 may decrease in a direction toward the first semiconductor layer SCL1.

In an embodiment, the inorganic insulating layers penetrated by the first contact hole CNH1 may have a tapered shape. A taper angle formed by side surfaces of the inorganic insulating layers (BF, GI1, GI2, GI3, ILD1) penetrated by the first contact hole CNH1 and a surface of the substrate SUB may have a value of 80 degrees or less.

For example, an inclination angle θ1 formed by side surfaces 1c of the buffer layer BF which face the first contact hole CNH1 and the first drain region D1 may be 80 degrees or less, an inclination angle θ2 formed by side surfaces 2c of the first gate insulating layer GI1 and the buffer layer BF may be 80 degrees or less, and an inclination angle θ3 formed by side surfaces 3c of the second gate insulating layer GI2 and the first gate insulating layer GI1 may be 80 degrees or less. In addition, an inclination angle θ4 formed by side surfaces 4c of the third gate insulating layer GI3 which face the first contact hole CNH1 and the second gate insulating layer GI2 may be 80 degrees or less, and an inclination angle θ5 formed by side surfaces 5c of the first insulating layer ILD1 and the third gate insulating layer GI3 may be 80 degrees or less.

The first auxiliary insulating layer AIL1 may be located on the first insulating layer ILD1. The first auxiliary insulating layer AIL1 may be located in the portion overlapping the first contact hole CNH1.

The first auxiliary insulating layer AIL1 may contact and cover an upper surface 5a of the first insulating layer ILD1 and may extend to contact and cover the side surfaces 1c of the buffer layer BF, the side surfaces 2c of the first gate insulating layer GI1, the side surfaces 3c of the second gate insulating layer GI2, the side surfaces 4c of the third gate insulating layer GI3, and the side surfaces 5c of the first insulating layer ILD1. That is, the first auxiliary insulating layer AIL1 may contact and cover sidewalls of the first contact hole CNH1.

The first auxiliary insulating layer AIL1 may define an insulating opening OP1. The insulating opening OP1 may be located in the portion overlapping the opening of the first contact hole CNH1. The first auxiliary insulating layer AIL1 may surround the insulating opening OP1.

In an embodiment, a width Wo1 of the insulating opening OP1 may be smaller than the width Wc1 of the first contact hole CNH1. The first contact hole CNH1 may completely surround the insulating opening OP1. For example, the width Wo1 of the insulating opening OP1 may have a value of 1.0 micrometer or less.

The first conductive pattern CP1 included in the fourth conductive layer GTL4 may contact the first drain region D1 included in the first semiconductor layer SCL1 in a portion overlapping the insulating opening OP1.

The insulating opening OP1 of an embodiment may include a contact opening OP1c. The contact opening OP1c may be defined by contact points ap where side surfaces a1 of the first auxiliary insulating layer AIL1 which face the first conductive pattern CP1 contact the first semiconductor layer SCL1.

In an embodiment, the first conductive pattern CP1 included in the fourth conductive layer GTL4 and the first drain region D1 included in the first semiconductor layer SCL1 may contact each other by a width Wo1c of the contact opening OP1c. For example, the width Wo1c of the contact opening OP1c may have a value of 0.8 micrometers or less.

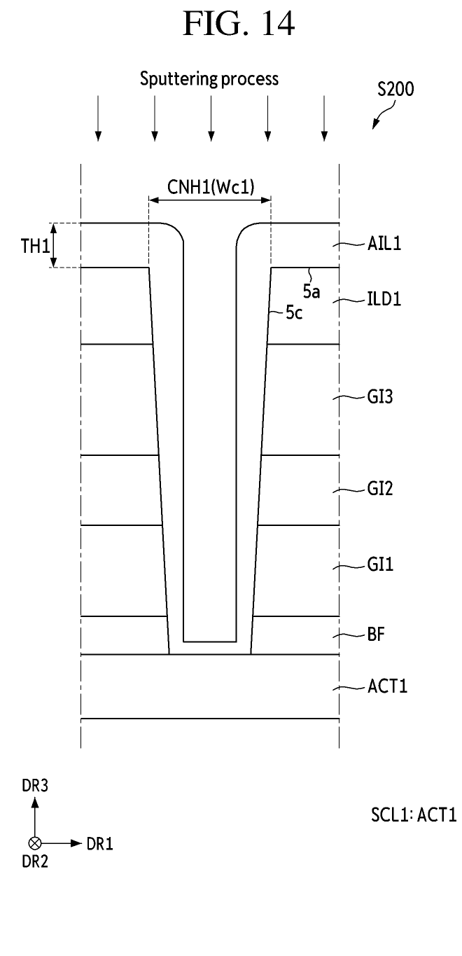

In the process of fabricating the display device 10, the first auxiliary insulating layer AIL1 may be deposited by a sputtering process (‘sputtering process’ of FIG. 14). Accordingly, the first auxiliary insulating layer AIL1 may have a non-uniform thickness TH1 in the portion overlapping the first contact hole CNH1. Specifically, the thickness TH1 of the first auxiliary insulating layer AIL1 may decrease as the depth of the first contact hole CNH1 increases. In other words, the thickness TH1 of the first auxiliary insulating layer AIL1 may decrease in the direction toward the first semiconductor layer SCL1. For example, the thickness TH1 of the first auxiliary insulating layer AIL1 may have a value of 0.6 micrometers or less.

Generally, in the sputtering process, deposition is performed using a phenomenon in which high-energy particles collide with a surface of a target material in a vacuum and transfer energy to target atoms on the surface, thereby ejecting the target atoms. Here, the ejected target materials have high straightness because they are moved by physical collision. Therefore, a deposition material formed by the sputtering process may be formed thickly in a relatively flat area and may be formed thinly in a curved or sunken area.

Specifically, the thickness TH1 of the first auxiliary insulating layer AIL1 may be divided into a first portion T11, a second portion T12, and a third portion T13 depending on position. The first portion T11 may be a portion in contact with the upper surface 5a of the first insulating layer ILD1, the second portion T12 may be a portion in contact with the side surfaces 5c of the first insulating layer ILD1, and the third portion T13 may be a portion in contact with the side surfaces of at least any one of the insulating layers (BF, GI1, GI2, GI3) located between the first insulating layer ILD1 and the first semiconductor layer SCL1.

In an embodiment, the first portion T11 may be thicker than the second portion T12, and the second portion T12 may be thicker than the third portion T13.

In addition, the thickness TH1 of the first auxiliary insulating layer AIL1 may include a fourth portion T14 located in a portion overlapping the contact opening OP1c in the first direction DR1. The fourth portion T14 may be a thinnest portion of the thickness TH1 of the first auxiliary insulating layer AIL1.

In an embodiment, the sum of the thickness TH1 of the first auxiliary insulating layer AIL1 and a thickness THa of the first insulating layer ILD1 may have a value of 1.5 micrometers or less. In addition, the thickness TH1 of the first auxiliary insulating layer AIL1 may be smaller than the thickness THa of the first insulating layer ILD1. For example, the thickness THa of the first insulating layer ILD1 may have a value of 1.2 micrometers or less.

The first conductive pattern CP1 may be located on the first auxiliary insulating layer AIL1. The first conductive pattern CP1 may cover the side surfaces (1c, 2c, 3c, 4c, 5c) of the insulating layers (BF, GI1, GI2, GI3, ILD1) which face the first contact hole CNH1 and the upper surface 5a of the first insulating layer ILD1 and may be spaced apart from the insulating layers (BF, GI1, GI2, GI3, ILD1) with the first auxiliary insulating layer AIL1. The first auxiliary insulating layer AIL1 may be located between the first conductive pattern CP1 and the insulating layers (BF, GI1, GI2, GI3, ILD1).

In some embodiments, the first conductive pattern CP1 may be formed with a uniform thickness along the profile of a structure under the first conductive pattern CP1. Therefore, the first conductive pattern CP1 of an embodiment may include a step in the portion overlapping the first contact hole CNH1.

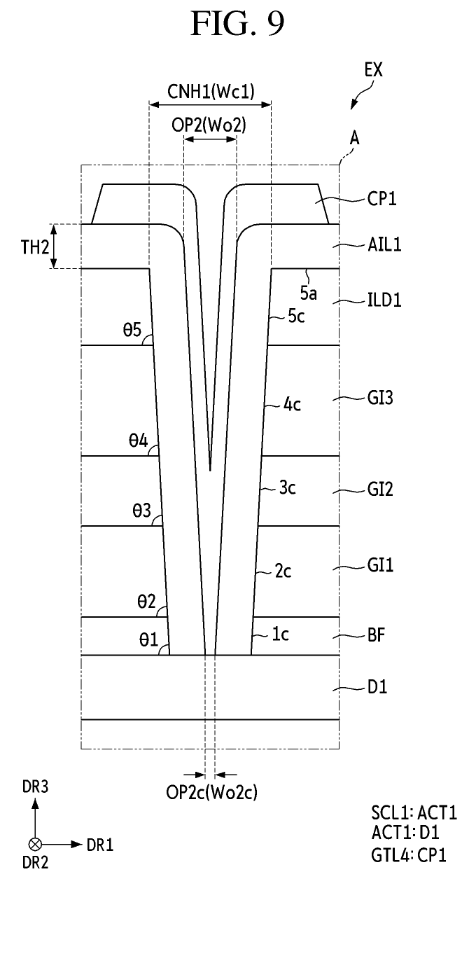

FIG. 9 is an enlarged cross-sectional view of area ‘A’ in FIG. 7 according to a comparative example.

Referring to FIGS. 8 and 9, a first auxiliary insulating layer AIL1 of the comparative example EX illustrated in FIG. 9 may be formed by a vapor deposition process. A description of common structures of the comparative example EX and the display device 10 will be omitted, and differences will be described below.

Generally, in the vapor deposition process, deposition is performed by vaporizing a material and adsorbing a precursor in a gaseous state onto a surface of a substrate. Here, the precursor in the gaseous state has low straightness because it is moved by gas diffusion. For example, the first auxiliary insulating layer AIL1 included in the comparative example EX may be formed by a chemical vapor deposition process.

The first auxiliary insulating layer AIL1 of the comparative example EX formed by the vapor deposition process may cover a structure under the first auxiliary insulating layer AIL1 with a uniform thickness along the profile of the structure. That is, a thickness TH2 of the first auxiliary insulating layer AIL1 included in the comparative example EX may have a uniform value within a process error range of 10% or less in a portion overlapping a first contact hole CNH1.

The first auxiliary insulating layer AIL1 of the comparative example EX may define an insulating opening OP2 in the portion overlapping the first contact hole CNH1. The insulating opening OP2 defined by the first auxiliary insulating layer AIL1 of the comparative example EX may have a reverse-tapered shape. In other words, a width Wo2 of the insulating opening OP2 may decrease in a direction toward a first semiconductor layer SCL1.

The insulating opening OP2 defined by the first auxiliary insulating layer AIL1 of the comparative example EX may include a contact opening OP2c. A first conductive pattern CP1 included in the comparative example EX and a first drain region D1 included in the first semiconductor layer SCL1 may contact each other by a width Wo2c of the contact opening OP2c.

Since the first auxiliary insulating layer AIL1 included in the comparative example EX has a uniform thickness TH2, the contact opening OP2c included in the comparative example EX may have a very narrow width. Therefore, a display device of the comparative example EX can cause a contact defect between the drain region D1 of the first semiconductor layer SCL1 and the first conductive pattern CP1.

In addition, since the thickness TH2 of the first auxiliary insulating layer AIL1 is thick overall, the contact opening OP2c may be formed with difficulty in a fabrication process of the comparative example EX.

To recapitulate with reference to FIGS. 1-9, in the display device 10 of the embodiment, the first contact hole CNH1 is formed by a photolithography process, and then the first auxiliary insulating layer AIL1 is formed by performing a sputtering process in a subsequent process. Accordingly, the contact opening OP1c where a semiconductor layer and a conductive layer contact each other may be formed to be 0.8 micrometers or less. Therefore, the display device 10 of the embodiment can provide a high-resolution display device.

Referring again to FIG. 7, the second conductive pattern CP2 may be electrically connected to the first source region S1 of the first active layer ACT1 through a first contact hole CNH1. In an embodiment, the second conductive pattern CP2 may be a source electrode of the first transistor T1 and may be considered as an element included in the first transistor T1. In an embodiment, all of the first contact holes CNH1 may have the same structure.

The third conductive pattern CP3 may contact the first gate electrode GE1 through a second contact hole CNH2.

The second contact hole CNH2 may penetrate a plurality of inorganic insulating layers. In an embodiment, the second contact hole CNH2 may penetrate four inorganic insulating layers. For example, the second contact hole CNH2 may penetrate the first gate insulating layer GI1, the second gate insulating layer GI2, the third gate insulating layer GI3, and the first insulating layer ILD1. The structure and characteristics of the second contact hole CNH2 may be the same as the structure and characteristics of the first contact hole CNH1.

Specifically, the second contact hole CNH2 may be formed by a photolithography process in the process of fabricating the display device 10. Accordingly, the inorganic insulating layers (GI1, GI2, GI3, ILD1) penetrated by the second contact hole CNH2 may have a tapered shape. Specifically, a taper angle formed by side surfaces of the inorganic insulating layers (GI1, GI2, GI3, ILD1) which face the second contact hole CNH2 and the surface of the substrate SUB may have a value of 80 degrees or less.

A width of the second contact hole CNH2 may have a reverse-tapered shape. The width of the second contact hole CNH2 may range from 1.0 micrometer to 1.5 micrometers.

The first auxiliary insulating layer AIL1 of an embodiment may extend from the portion overlapping the first contact hole CNH1 to a portion overlapping the second contact hole CNH2. The first auxiliary insulating layer AIL1 may contact and cover sidewalls of the second contact hole CNH2.

An insulating opening defined by the first auxiliary insulating layer AIL1 may be located in the portion overlapping the second contact hole CNH2, and the second contact hole CNH2 may completely surround the insulating opening.

The insulating opening defined by the first auxiliary insulating layer AIL1 may include a contact opening, and the first gate electrode GE1 and the third conductive pattern CP3 may contact each other in a portion overlapping the contact opening. The contact opening of the first auxiliary insulating layer AIL1 located in the portion overlapping the second contact hole CNH2 may be in a range of 0.8 micrometers or less. Redundant descriptions are omitted.

The fourth conductive pattern CP4 may contact the first capacitor electrode CPE1 in a portion overlapping a third contact hole CNH3, and the fourth conductive pattern CP4 and the first capacitor electrode CPE1 may be electrically connected. For example, the third contact hole CNH3 may penetrate the second gate insulating layer GI2, the third gate insulating layer GI3, and the first insulating layer ILD1. The third contact hole CNH3 will be described later.

The second insulating layer ILD2 may be located on the first auxiliary insulating layer AIL1 and the fourth conductive layer GTL4. The second insulating layer ILD2 may cover the entire fourth conductive layer GTL4.

The second insulating layer ILD2 may include an inorganic insulating material.

A second auxiliary insulating layer AIL2 may be located on the second insulating layer ILD2. The second auxiliary insulating layer AIL2 may cover the entire second insulating layer ILD2.

The second auxiliary insulating layer AIL2 may include an inorganic insulating material. For example, the second auxiliary insulating layer AIL2 may include at least any one of silicon nitride (e.g., Si₃N₄ or SiNₓ) and silicon oxynitride (e.g., SiON).

The first source-drain layer SDL1 may be located on the second auxiliary insulating layer AIL2. The first source-drain layer SDL1 may include a conductive material. Examples of the conductive material are omitted.

The first source-drain layer SDL1 may include a fifth conductive pattern CP5, the sixth conductive pattern CP6, and the second capacitor electrode CPE2.

The second capacitor electrode CPE2 may overlap a data line DL connected to the pixel PX. The second capacitor electrode CPE2 and the data line DL may form a second capacitor C2. The second capacitor electrode CPE2 and the data line DL may form a first electrode and a second electrode of the second capacitor C2, respectively.

The second capacitor electrode CPE2 may be electrically connected to the second drain region D2 of the second active layer ACT2 and the third source region S3 of the third active layer ACT3 through another third contact hole CNH3. The second capacitor electrode CPE2 may be a drain electrode of the second transistor T2 and a source electrode of the third transistor T3 and may be considered as an element included in the second transistor T2 and the third transistor T3.

In an embodiment, the fifth conductive pattern CP5 included in the first source-drain layer SDL1 may be connected to the third drain region D3 through a third contact hole CNH3, the sixth conductive pattern CP6 may be connected to the second source region S2 through another third contact hole CNH3, and the second capacitor electrode CPE2 may be connected to the second drain region D2 and the third source region S3 through another third contact hole CNH3.

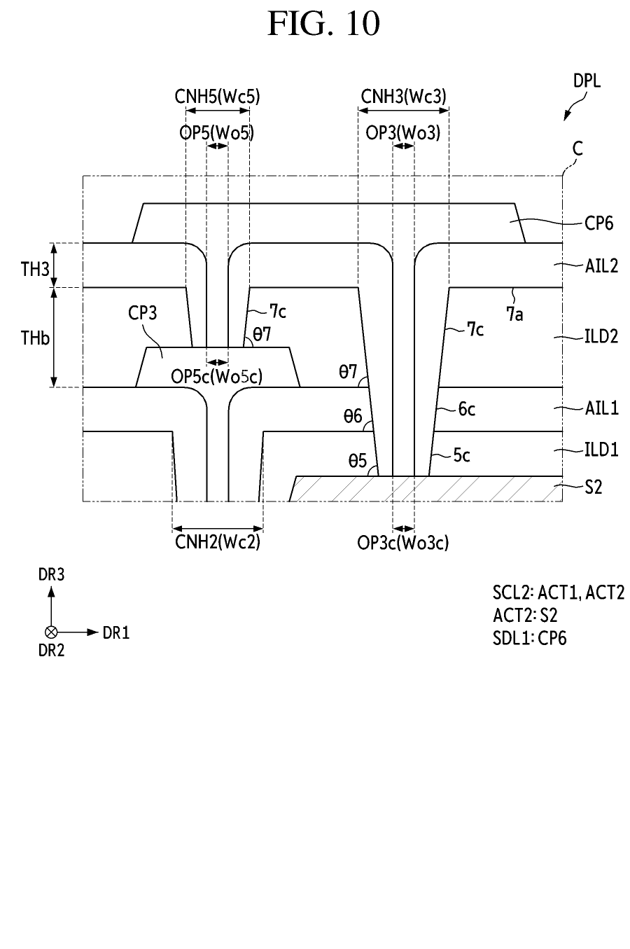

FIG. 10 is an enlarged cross-sectional view of area ‘C’ in FIG. 7.

Referring to FIG. 10 in addition to FIGS. 1-9, a third contact hole CNH3 of an embodiment may penetrate three inorganic insulating layers. For example, the third contact hole CNH3 may penetrate the first insulating layer ILD1, the first auxiliary insulating layer AIL1, and the second insulating layer ILD2.

In an embodiment, the third contact hole CNH3 may have a reverse-tapered shape. That is, a width Wc3 of the third contact hole CNH3 may decrease as a depth of the third contact hole CNH3 increases. The width Wc3 of the third contact hole CNH3 may range from 1.0 micrometer to 1.5 micrometers.

In an embodiment, the inorganic insulating layers penetrated by the third contact hole CNH3 may have a tapered shape. A taper angle formed by side surfaces of the inorganic insulating layers (ILD1, AIL1, ILD2) penetrated by the third contact hole CNH3 and the surface of the substrate SUB may have a value of 80 degrees or less.

For example, an inclination angle θ5 formed by the side surfaces 5c of the first insulating layer ILD1 which face the third contact hole CNH3 and the second source region S2 may be 80 degrees or less, an inclination angle θ6 formed by side surfaces 6c of the first auxiliary insulating layer AIL1 and the first insulating layer ILD1 may be 80 degrees or less, and an inclination angle θ7 formed by side surfaces 7c of the second insulating layer ILD2 and the first auxiliary insulating layer AIL1 may be 80 degrees or less.

The second auxiliary insulating layer AIL2 may be located in a portion overlapping the third contact hole CNH3. The second auxiliary insulating layer AIL2 may contact and cover an upper surface 7a of the second insulating layer ILD2 and may extend to contact and cover the side surfaces 5c of the first insulating layer ILD1, the side surfaces 6c of the first auxiliary insulating layer AIL1 and the side surfaces 7c of the second insulating layer ILD2. That is, the second auxiliary insulating layer AIL2 may contact and cover sidewalls of the third contact hole CNH3.

The second auxiliary insulating layer AIL2 may include an insulating opening OP3 in the portion overlapping the third contact hole CNH3. The insulating opening OP3 may be located in the portion overlapping the third contact hole CNH3. The second auxiliary insulating layer AIL2 may surround the insulating opening OP3.

In an embodiment, a width Wo3 of the insulating opening OP3 may be smaller than the width Wc3 of the third contact hole CNH3. The third contact hole CNH3 may completely surround the insulating opening OP3. For example, the width Wo3 of the insulating opening OP3 may have a value of 1.0 micrometer or less.

The insulating opening OP3 of an embodiment may include a contact opening OP3c. The sixth conductive pattern CP6 included in the first source-drain layer SDL1 and the second source region S2 included in the second semiconductor layer SCL2 may contact each other by a width Wo3c of the contact opening OP3c. For example, the width Wo3c of the contact opening OP3c may have a value of 0.8 micrometers or less.

The second auxiliary insulating layer AIL2 may have a non-uniform thickness TH3 in the portion overlapping the third contact hole CNH3. Specifically, the thickness TH3 of the second auxiliary insulating layer AIL2 may decrease as the depth of the third contact hole CNH3 increases. In other words, the thickness TH3 of the second auxiliary insulating layer AIL2 may decrease in a direction toward the second semiconductor layer SCL2. Redundant descriptions are omitted.

In an embodiment, the sum of the thickness TH3 of the second auxiliary insulating layer AIL2 and a thickness THb of the second insulating layer ILD2 may have a value of 1.5 micrometers or less, and the thickness TH3 of the second auxiliary insulating layer AIL2 may be smaller than the thickness THb of the second insulating layer ILD2. For example, the thickness TH3 of the second auxiliary insulating layer AIL2 may be 0.6 micrometers or less, and the thickness THb of the second insulating layer ILD2 may be 1.2 micrometers or less.

The sixth conductive pattern CP6 may cover the side surfaces (5c, 6c, 7c) of the insulating layers (ILD1, AIL1, ILD2) which face the third contact hole CNH3 and the upper surface 7a of the second insulating layer ILD2 and may be spaced apart from the insulating layers (ILD1, AIL1, ILD2) with the second auxiliary insulating layer AIL2. The second auxiliary insulating layer AIL2 may be located between the sixth conductive pattern CP6 and the insulating layers (ILD1, AIL1, ILD2).

In some embodiments, the sixth conductive pattern CP6 may completely fill the inside of the insulating opening OP3. Accordingly, the sixth conductive pattern CP6 may not include a step in the portion overlapping the third contact hole CNH3.

In an embodiment, the sixth conductive pattern CP6 may cover a structure under the sixth conductive pattern CP6 with a uniform thickness along the profile of the structure. In this case, the sixth conductive pattern CP6 may include a step in the portion overlapping the third contact hole CNH3.

In the display device 10 of the embodiment, the third contact hole CNH3 is formed by a photolithography process, and then the second auxiliary insulating layer AIL2 is formed by performing a sputtering process in a subsequent process. Accordingly, the contact opening OP3c where a semiconductor layer and a source-drain conductive layer contact each other may be formed to be 0.8 micrometers or less. Therefore, the display device 10 of the embodiment can provide a high-resolution display device.

In an embodiment, the fifth conductive pattern CP5 included in the first source-drain layer SDL1 may be connected to the first conductive pattern CP1 included in the fourth conductive layer GTL4 through a fifth contact hole CNH5, and the sixth conductive pattern CP6 may be connected to the third conductive pattern CP3 included in the fourth conductive layer GTL4 through another fifth contact hole CNH5.

A fifth contact hole CNH5 of an embodiment may penetrate one inorganic insulating layer. For example, the fifth contact hole CNH5 may penetrate the second insulating layer ILD2.

In an embodiment, the fifth contact hole CNH5 may have a reverse-tapered shape. That is, a width Wc5 of the fifth contact hole CNH5 may decrease as a depth of the fifth contact hole CNH5 increases. The width Wc5 of the fifth contact hole CNH5 may range from 1.0 micrometer to 1.5 micrometers.

In an embodiment, the inorganic insulating layer penetrated by the fifth contact hole CNH5 may have a tapered shape. A taper angle of the second insulating layer ILD2 penetrated by the fifth contact hole CNH5 may have a value of 80 degrees or less. For example, an inclination angle θ7 formed by the side surfaces 7c of the second insulating layer ILD2 and the third conductive pattern CP3 may be 80 degrees or less.

The second auxiliary insulating layer AIL2 may extend from the portion overlapping the third contact hole CNH3 to a portion overlapping the fifth contact hole CNH5. The second auxiliary insulating layer AIL2 may contact and cover sidewalls of the fifth contact hole CNH5.

The second auxiliary insulating layer AIL2 may define an insulating opening OP5. The insulating opening OP5 may be located in the portion overlapping the fifth contact hole CNH5. The second auxiliary insulating layer AIL2 may surround the insulating opening OP5.

In an embodiment, a width Wo5 of the insulating opening OP5 may be smaller than the width Wc5 of the fifth contact hole CNH5. Therefore, the fifth contact hole CNH5 may completely surround the insulating opening OP5. For example, the width Wo5 of the insulating opening OP5 may have a value of 1.0 micrometer or less.

The insulating opening OP5 may include a contact opening OP5c. The sixth conductive pattern CP6 included in the first source-drain layer SDL1 may contact the third conductive pattern CP3 included in the fourth conductive layer GTL4 in a portion overlapping the contact opening OP5c. For example, a width Wo5c of the contact opening OP5c may have a value of 0.8 micrometers or less.

In some embodiments, the sixth conductive pattern CP6 may completely fill the inside of the insulating opening OP5. Accordingly, the sixth conductive pattern CP6 may not include a step in the portion overlapping the fifth contact hole CNH5.

In the display device 10 of the embodiment, the fifth contact hole CNH5 is formed by a photolithography process, and then the second auxiliary insulating layer AIL2 is formed by performing a sputtering process in a subsequent process. Accordingly, the contact opening OP5c where a conductive layer and a source-drain conductive layer contact each other may be formed to be 0.8 micrometers or less. Therefore, the display device 10 of the embodiment can provide a high-resolution display device.

Referring again to FIG. 7, the third insulating layer ILD3 may be located on the second auxiliary insulating layer AIL2 and the first source-drain layer SDL1. The third insulating layer ILD3 may cover the entire first source-drain layer SDL1. The third insulating layer ILD3 may include an inorganic insulating material.

The second source-drain layer SDL2 may be located on the third insulating layer ILD3. The second source-drain layer SDL2 may include a conductive material.

The second source-drain layer SDL2 may include the data line DL connected to the pixel PX. The data line DL may form the second capacitor C2 together with the second capacitor electrode CPE2.

The fourth insulating layer ILD4 may be located on the third insulating layer ILD3 and the second source-drain layer SDL2. The fourth insulating layer ILD4 may cover the entire second source-drain layer SDL2. The fourth insulating layer ILD4 may include the inorganic insulating material included in the third insulating layer ILD3.

A third auxiliary insulating layer AIL3 may be located on the fourth insulating layer ILD4 and the second source-drain layer SDL2. The third auxiliary insulating layer AIL3 may cover the entire fourth insulating layer ILD4.

The third auxiliary insulating layer AIL3 may include an inorganic insulating material. For example, the third auxiliary insulating layer AIL3 may include at least any one of silicon nitride (e.g., Si₃N₄ or SiNₓ) and silicon oxynitride (e.g., SiON).

The third source-drain layer SDL3 may be located on the third auxiliary insulating layer AIL3. The third source-drain layer SDL3 may include a conductive material.

The third source-drain layer SDL3 may include a seventh conductive pattern CP7, an eighth conductive pattern CP8, and a ninth conductive pattern CP9.

In an embodiment, the seventh conductive pattern CP7 may be connected to the fifth conductive pattern CP5 through a fourth contact hole CNH4, the eighth conductive pattern CP8 may contact the second conductive pattern CP2 through a second contact hole CNH2, and the ninth conductive pattern CP9 may contact the fourth conductive pattern CP4 through another second contact hole CNH2. For example, the seventh conductive pattern CP7 may be an anode connection electrode, the eighth conductive pattern CP8 may be a voltage line of the pixel PX, and the ninth conductive pattern CP9 may be an initialization voltage line of the pixel PX.

The fourth contact hole CNH4 of an embodiment may penetrate two inorganic insulating materials. For example, the fourth contact hole CNH4 may penetrate the third insulating layer ILD3 and the fourth insulating layer ILD4. The structure of the fourth contact hole CNH4 may be the same as the structure of the first contact hole CNH1. Redundant descriptions are omitted.

In the display device 10 of the embodiment, the fourth contact hole CNH4 is formed by a photolithography process, and then the third auxiliary insulating layer AIL3 is formed by performing a sputtering process in a subsequent process. Accordingly, a contact opening where a source-drain conductive layer and a source-drain conductive layer contact each other may be formed to be 0.8 micrometers or less. Therefore, the display device 10 of the embodiment can provide a high-resolution display device.

The via layer VIA may be located on the third auxiliary insulating layer AIL3 and the third source-drain layer SDL3. The via layer VIA may cover the entire third source-drain layer SDL3.

The via layer VIA may include an organic material. For example, the via layer VIA may include acryl resin, epoxy resin, phenolic resin, polyamide resin, or polyimide resin.

The display element layer EML may be located on the transistor layer TFTL. The display element layer EML may include a light emitting element ED and a pixel defining layer PDL. The light emitting element ED may include an anode AE, a light emitting layer EL, and a cathode CE.

The anode AE of the light emitting element ED may be located on the via layer VIA. The anode AE may be connected to the seventh conductive pattern CP7 of the third source-drain layer SDL3 through an anode contact hole VH penetrating the via layer VIA.

The anode AE may be formed as a single layer of silver (Ag), molybdenum (Mo), titanium (Ti), copper (Cu) or aluminum (Al) or, in order to increase reflectivity, may be formed as a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide. The APC alloy is an alloy of silver (Ag), palladium (Pd), and copper (Cu).

The pixel defining layer PDL may be located on the via layer VIA. The pixel defining layer PDL may define an emission opening EOP and expose the anode AE in a portion overlapping the emission opening EOP. The pixel defining layer PDL may cover edges of the anode AE. In an embodiment, an emission area EA may be defined by the emission opening EOP.

The pixel defining layer PDL may include an organic material or an inorganic material.

For example, when the pixel defining layer PDL includes an organic material, the pixel defining layer PDL may include acryl resin, epoxy resin, phenolic resin, polyamide resin, or polyimide resin.

For example, when the pixel defining layer PDL includes an inorganic material, the pixel defining layer PDL may include silicon nitride (e.g., Si₃N₄ or SiNₓ), silicon oxide (e.g., SiO₂ or SiOₓ), silicon oxynitride (e.g., SiON), titanium oxide, aluminum oxide, or other inorganic insulating materials.

The light emitting layer EL of the light emitting element ED may be located on the anode AE. The light emitting layer EL may include an organic material to emit light of a selected color. For example, the light emitting layer EL may include a hole transporting layer, an organic material layer, and an electron transporting layer. The organic material layer may include a host and a dopant. The organic material layer may include a material that emits selected light and may be formed using a phosphorescent material or a fluorescent material.

The cathode CE of the light emitting element ED may be located on the light emitting layer EL. The cathode CE may cover the light emitting layer EL. The cathode CE may be a common layer located in common on a plurality of light emitting layers EL.

The cathode CE may include a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag. When the cathode CE includes a semi-transmissive conductive material, light output efficiency may be increased by a microcavity.

The encapsulation layer TFEL may be formed on the display element layer EML. The encapsulation layer TFEL may include at least one inorganic layer to prevent oxygen or moisture from penetrating into the display element layer EML. In addition, the encapsulation layer TFEL may include at least one organic layer to protect the display element layer EML from foreign substances such as dust.

The encapsulation layer TFEL may include a first encapsulation layer TFE1, a second encapsulation layer TFE2, and a third encapsulation layer TFE3.

The first encapsulation layer TFE1 may be located on the cathode CE and may cover the entire cathode CE.

The first encapsulation layer TFE1 may include an inorganic insulating material, for example, may include silicon nitride (e.g., Si₃N₄ or SiNₓ), silicon oxide (e.g., SiO₂ or SiOₓ), silicon oxynitride (e.g., SiON), titanium oxide, aluminum oxide, or other inorganic insulating materials.

The second encapsulation layer TFE2 may be located on the first encapsulation layer TFE1 and may cover the entire first encapsulation layer TFE1. The second encapsulation layer TFE2 may planarize a step formed by the first encapsulation layer TFE1.

The second encapsulation layer TFE2 may include an organic material and may be, for example, an organic layer such as acryl resin, epoxy resin, silicone resin, silicone-acryl resin, phenolic resin, polyamide resin, or polyimide resin.

The third encapsulation layer TFE3 may be located on the second encapsulation layer TFE2 and may cover the entire second encapsulation layer TFE2.

The third encapsulation layer TFE3 may include an inorganic insulating material, for example, may include silicon nitride (e.g., Si₃N₄ or SiNₓ), silicon oxide (e.g., SiO₂ or SiOₓ), silicon oxynitride (e.g., SiON), titanium oxide, aluminum oxide, or other inorganic insulating materials.

In an embodiment, the display device 10 may further include an optical layer located on the encapsulation layer TFEL. The optical layer may include at least one of a color filter layer (e.g., a color filter layer including color filters corresponding to emission colors of pixels PX) and a light conversion layer (e.g., a light conversion layer including wavelength conversion patterns that convert the colors or wavelengths of light emitted from light emitting elements ED of at least some of the pixels PX).

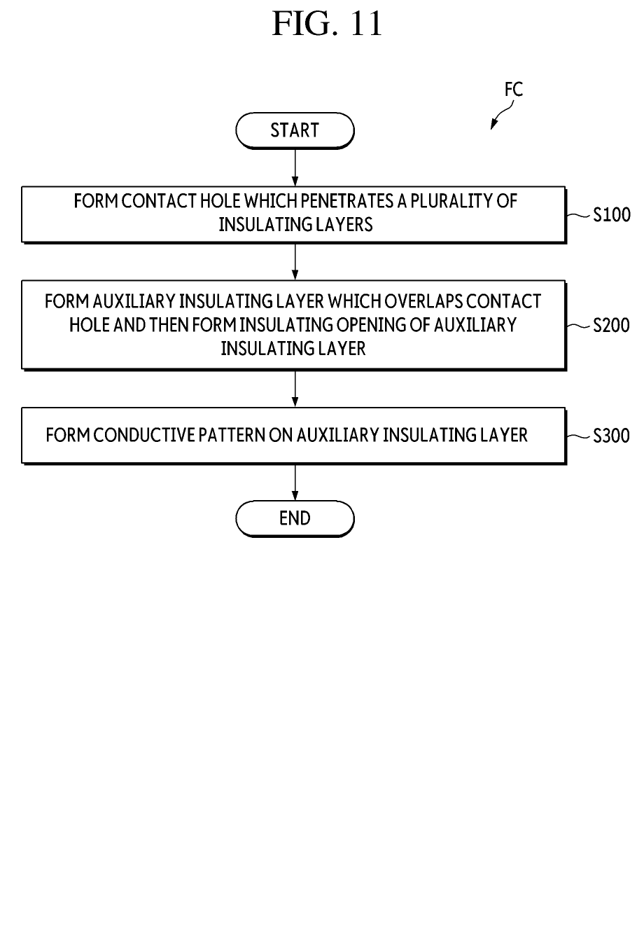

FIG. 11 is a flowchart illustrating a process of fabricating a plurality of insulating layers, a first auxiliary insulating layer, and a first conductive pattern which overlap a first contact hole in FIG. 8.

Referring to FIG. 11, a method FC of fabricating a display device 10 according to an embodiment may include forming a contact hole which penetrates a plurality of insulating layers (operation S100), forming an auxiliary insulating layer which overlaps the contact hole and then forming an insulating opening of the auxiliary insulating layer (operation S200), and forming a conductive pattern on the auxiliary insulating layer (operation S300).

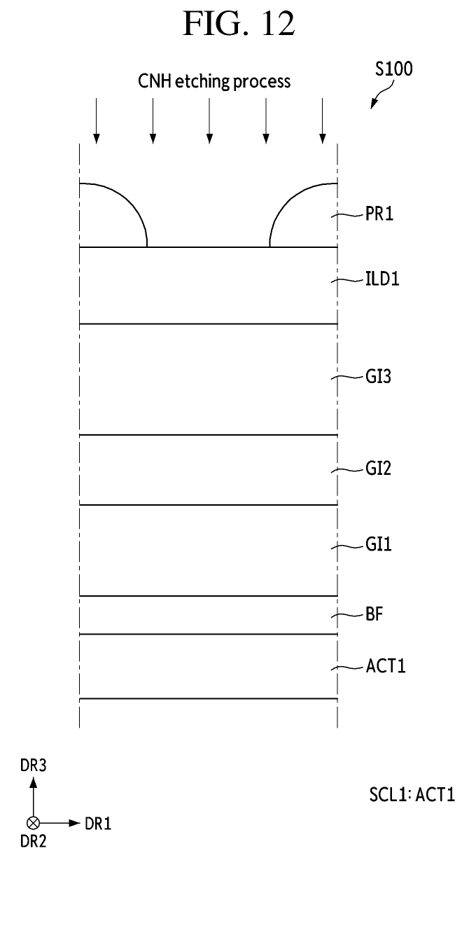

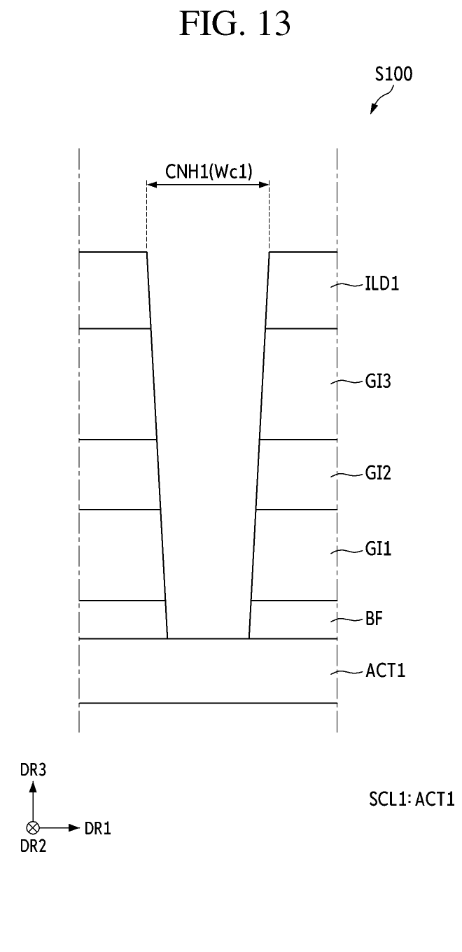

FIGS. 12 and 13 are cross-sectional views illustrating operation S100 of FIG. 11.

The forming of the contact hole which penetrates the insulating layers (operation S100) will be described with reference to FIGS. 12 and 13 in addition to FIGS. 1-11.

First, a first active layer ACT1 included in a first semiconductor layer SCL1 is formed on a substrate SUB. The first active layer ACT1 may be divided into multiple regions having different characteristics as illustrated in FIG. 7. For example, a first source region S1 and a first drain region D1 may be conductive regions compared with a first channel region CHA1. Redundant descriptions are omitted. In the present specification, the first active layer ACT1 may be referred to as a semiconductor and/or a semiconductor layer.

In the current process, the first active layer ACT1 may be formed through a semiconductor layer forming process and a semiconductor patterning process.

Next, a plurality of insulating layers is sequentially deposited on the first active layer ACT1. For example, the insulating layers may include a buffer layer BF, a first gate insulating layer GI1, a second gate insulating layer GI2, a third gate insulating layer GI3, and a first insulating layer ILD1. The buffer layer BF, the first gate insulating layer GI1, the second gate insulating layer GI2, the third gate insulating layer GI3, and the first insulating layer ILD1 may be formed over the entire surface.

The buffer layer BF, the first gate insulating layer GI1, the second gate insulating layer GI2, the third gate insulating layer GI3, and the first insulating layer ILD1 may be formed through a deposition process for forming a layer of an insulating material (e.g., an inorganic insulating material) exemplified above.

Next, a first contact hole CNH1 is formed by performing a photolithography process.

First, photoresists PR1 are formed on the first insulating layer ILD1. In the current process, a plurality of photoresists PR1 may be formed and spaced apart from each other.

Next, a contact hole etching process (CNH etching process) is performed. For example, the CNH etching process may be performed as a dry etching process.

For example, the dry etching process may be performed through a reactive ion etching (RIE) process using a reaction gas such as CHF₃, CH₃F, CH₂F₂, CHF₆, CF₄, C₂F₆ or C₃F₆ and a sputtering gas such as Ar or O₂/Ar. In this case, an inductively coupled plasma (ICP) source or a capacitively coupled plasma (CCP) source may be used as a plasma source.

In the current process, a portion of the buffer layer BF, the first gate insulating layer GI1, the second gate insulating layer GI2, the third gate insulating layer GI3 and the first insulating layer ILD1 which is not overlapped by the photoresists PR1 may all be removed at once to form an opening. The first active layer ACT1 included in the first semiconductor layer SCL1 may be exposed in a portion overlapping the opening. The opening may be referred to as the first contact hole CNH1.

In the current process, the first contact hole CNH1 may have a reverse-tapered shape as it is formed by a photolithography process. Accordingly, a width Wc1 of the first contact hole CNH1 may decrease in a direction toward the first semiconductor layer SCL1. In the current process, the width Wc1 of the first contact hole CNH1 may range from 1.0 micrometer to 1.5 micrometers.

In the current process, the buffer layer BF, the first gate insulating layer GI1, the second gate insulating layer GI2, the third gate insulating layer GI3, and the first insulating layer ILD1 penetrated by the first contact hole CNH1 may have a tapered shape. A taper angle of each of the inorganic insulating layers (BF, GI1, GI2, GI3, ILD1) may have a value of 80 degrees or less. Redundant descriptions are omitted.

For example, if the inorganic insulating layers (BF, GI1, GI2, GI3, ILD1) have a taper angle of greater than 80 degrees (e.g., if formed vertically), when the first auxiliary insulating layer AIL1 is formed in a subsequent process, an entrance portion of the first contact hole CNH1 may be blocked by the first auxiliary insulating layer AIL1. Therefore, it may be important to form the inorganic insulating layers (BF, GI1, GI2, GI3, ILD1) to have a taper angle of 80 degrees or less.

FIGS. 14-16 are cross-sectional views illustrating operation S200 of FIG. 11.

The forming of the auxiliary insulating layer which overlaps the contact hole and then the forming of the insulating opening of the auxiliary insulating layer (operation S200) will be described with reference to FIGS. 14-16 in addition to FIGS. 1-13.

First, a first auxiliary insulating layer AIL1 is formed on the first insulating layer ILD1. In the current process, the first auxiliary insulating layer AIL1 may be deposited by performing a sputtering process.

In the current process, the first auxiliary insulating layer AIL1 may contact and cover an upper surface 5a and side surfaces 5c of the first insulating layer ILD1 and may extend to contact and cover sidewalls of the first contact hole CNH1 (e.g., side surfaces of the inorganic insulating layers (BF, GI1, GI2, GI3, ILD1) which face the first contact hole CNH1). In addition, the first auxiliary insulating layer AIL1 may contact and cover a portion of an upper surface of the first semiconductor layer SCL1 in a portion overlapping the first contact hole CNH1.

In the current process, the first auxiliary insulating layer AIL1 may have an overhang step coverage characteristic. The overhang step coverage characteristic may mean that the first auxiliary insulating layer AIL1 is formed thickest on the upper surface 5a of the first insulating layer ILD1 having a relatively flat surface and is formed thinnest on the first semiconductor layer SCL1 located in a relatively curved portion. In other words, it may mean that the first auxiliary insulating layer AIL1 is formed thicker in an upper area of the first contact hole CNH1 than in a lower area of the first contact hole CNH1.

In other words, a thickness TH1 of the first auxiliary insulating layer AIL1 may decrease as a depth of the first contact hole CNH1 increases and may increase in a direction toward an entrance of the first contact hole CNH1. The first auxiliary insulating layer AIL1 may be thickest on the upper surface 5a of the first insulating layer ILD1. As described above, this may be a major characteristic caused by the high straightness of the sputtering process. Redundant descriptions omitted.

Next, an insulating opening is formed by a photolithography process.

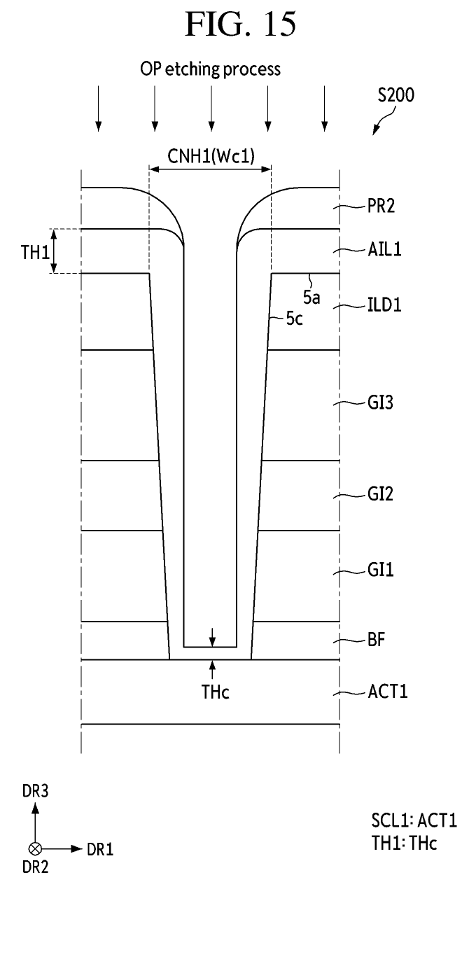

As illustrated in FIG. 15, photoresists PR2 are formed on the first auxiliary insulating layer AIL1. In the current process, a plurality of photoresists PR2 may be formed and spaced apart from each other.

Next, an insulating opening etching process (OP etching process) is performed. The OP etching process may be performed as a dry etching process.

In the current process, since the dry etching process is characterized by being performed vertically, the first auxiliary insulating layer AIL1 not overlapped by the photoresists PR2 may be removed. Accordingly, the first active layer ACT1 included in the first semiconductor layer SCL1 not overlapped by the photoresists PR2 may be exposed.

In the current process, a thickness THc of the first auxiliary insulating layer AIL1 not overlapped by the photoresists PR2 may be a thinnest portion of the thickness TH1 of the first auxiliary insulating layer AIL1. Therefore, in the current process, the first auxiliary insulating layer AIL1 not overlapped by the photoresists PR2 can be easily removed within a short process time. Accordingly, the current process can be performed without a damage defect to the first auxiliary insulating layer AIL1 overlapped by the photoresists PR2.

Through the current process, the first auxiliary insulating layer AIL1 may include an insulating opening OP1. The first auxiliary insulating layer AIL1 may surround the insulating opening OP1. For example, a width Wo1 of the insulating opening OP1 may have a value of 1.0 micrometer or less.

In the current process, the insulating opening OP1 may include a contact opening OP1c, and the first semiconductor layer SCL1 may be exposed by a width Wo1c of the contact opening OP1c. For example, the width Wo1c of the contact opening OP1c may have a value of 0.8 micrometer or less. Redundant descriptions regarding the definition of the contact opening OP1care omitted.

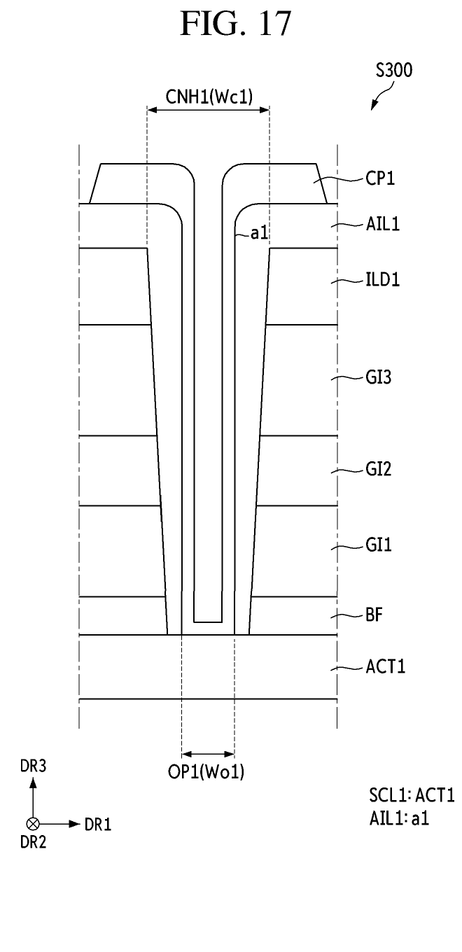

FIG. 17 is a cross-sectional view illustrating operation S300 of FIG. 11.

The forming of the conductive pattern on the auxiliary insulating layer (operation S300) will be described with reference to FIG. 17 in addition to FIGS. 1-16.

Next, a first conductive pattern CP1 is formed on the first auxiliary insulating layer AIL1. The process of forming the first conductive pattern CP1 may be performed by deposition and patterning processes including at least any one of the conductive materials described above.

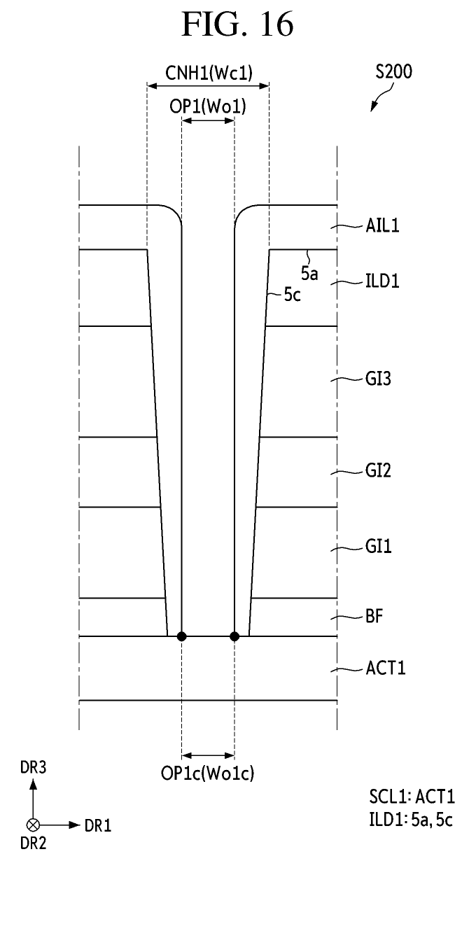

In the current process, the first conductive pattern CP1 may contact and cover side surfaces a1 of the first element insulating layer AIL1 in the portion overlapping the first contact hole CNH1. In addition, the first conductive pattern CP1 may contact the first semiconductor layer SCL1 in a portion overlapping the insulating opening OP1. Referring to FIG. 16, the first conductive pattern CP1 and the first semiconductor layer SCL1 may contact each other by the width Wo1c of the contact opening OP1c.

Consequently, the insulating layers (BF, GI1, GI2, GI3, ILD1), the first auxiliary insulating layer AIL1, and the first conductive pattern CP1 overlapping the first contact hole CNH1 illustrated in FIG. 8 may be formed.

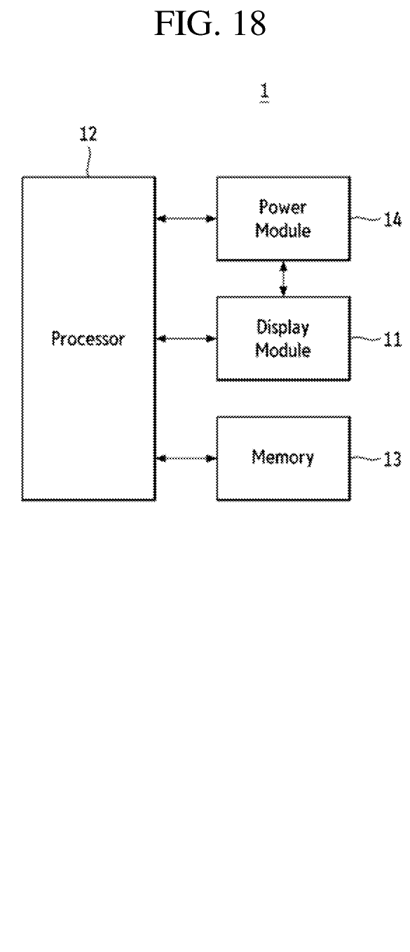

FIG. 18 is a block diagram of an electronic device 1 according to an embodiment.

Referring to FIG. 18 in addition to FIGS. 1-17, the display device 10 according to the embodiment can be applied to various electronic devices 1. The electronic device 1 according to an embodiment includes the above-described display device 10 and may further include modules or devices having other additional functions, in addition to the display device 10.

The electronic device 1 according to the embodiment may include a display module 11, a processor 12, a memory 13, and a power module 14.

The processor 12 may include one or more processors and may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module. The power conversion module may generate power necessary for the operation of the electronic device 1 by converting power supplied by the power supply module.

At least one of the elements of the electronic device 1 described above may be included in a display device according to the above-described embodiments. In addition, some of individual modules functionally included in one module may be included in the display device, and other modules may be provided separately from the display device. For example, the display device may include the display module 11, and the processor 12, the memory 13 and the power module 14 may be provided not in the display device but in the form of other devices within the electronic device 1.

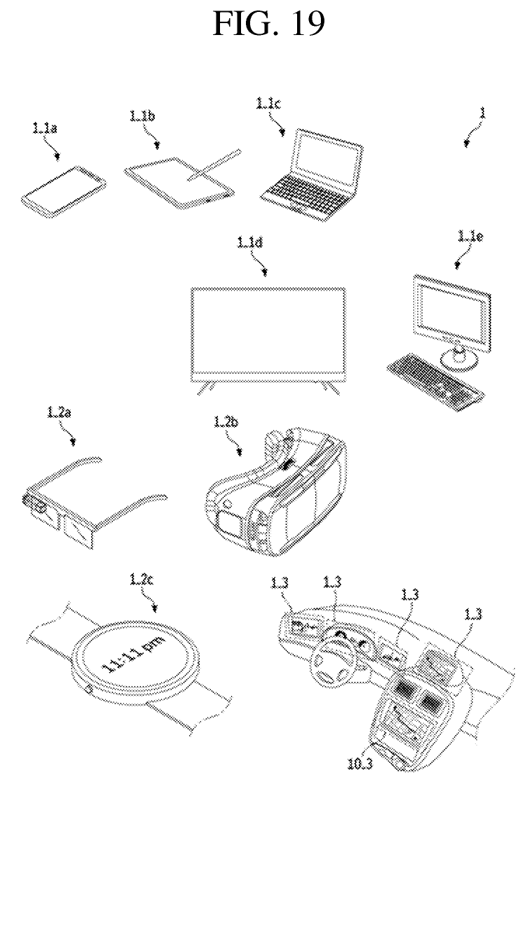

FIG. 19 is a schematic diagram of electronic devices according to various embodiments.

Referring to FIG. 19, various electronic devices 1 to which a display device 10 according to embodiments is applied may include image display electronic devices such as a smartphone 1_1a, a tablet PC 1_1b, a laptop 1_1c, a television 1_1d, and a desk monitor 1_1e. In addition, the various electronic devices 1 to which the display device 10 according to the embodiments is applied may include wearable electronic devices including a display module, such as smart glasses 1_2a, a head-mounted display 1_2b and a smart watch 1_2c, and vehicle electronic devices 1_3 including a display module, such as a center information display (CID) and a room mirror display placed on an instrument cluster, center fascia and dashboard of a vehicle.

In concluding the detailed description, those skilled in the art will appreciate that many variations and modifications can be made to the embodiments without substantially departing from the principles of the present disclosure. Therefore, the disclosed embodiments of the inventive concept are used in a generic and descriptive sense only and not for purposes of limitation. The scope of the present disclosure is represented by the scope of the accompanying claims, rather than the detailed description. All changes or modifications derived from the meaning and scope of the claims and equivalent concepts thereof should be interpreted as being included in the scope of the present disclosure.

Although the embodiments of the present disclosure have been described with reference to the accompanying drawings, it will be apparent to those skilled in the art that the present disclosure can be embodied in other specific forms without departing from the technical spirits and essential characteristics. Thus, the above embodiments are to be considered in all respects as illustrative and not restrictive.

The embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it should be understood that the embodiments described above are illustrative in all aspects and not restrictive.

Features of various embodiments of the disclosure may be combined partially or totally. As will be clearly appreciated by those skilled in the art, technically various interactions and operations are possible. Also, various embodiments can be practiced individually or in combination.

In concluding the detailed description, those skilled in the art will appreciate that many variations and modifications can be made to the described embodiments without substantially departing from the principles of the inventive concept. Therefore, the disclosed embodiments of the inventive concept are used in a generic and descriptive sense and not for purposes of limitation.

What is claimed is:

1. A display device comprising:
a substrate comprising a semiconductor layer;
a first insulating layer located on the semiconductor layer;
a first contact hole comprising an opening which extends through the first insulating layer to the semiconductor layer;
a conductive layer located on the first insulating layer and contacting the semiconductor layer in a portion overlapping the first contact hole; and
a first auxiliary insulating layer located between the first insulating layer and the conductive layer and defining an insulating opening,
wherein the insulating opening overlaps the first contact hole, a width of the insulating opening is smaller than a width of the first contact hole, and a thickness of the first auxiliary insulating layer decreases in a direction toward the semiconductor layer in the portion overlapping the first contact hole.

2. The display device of claim 1, wherein the insulating opening comprises a contact opening, and the semiconductor layer and the conductive layer contact each other in a portion overlapping the contact opening.

3. The display device of claim 2, wherein a width of the contact opening is 0.8 micrometers or less.

4. The display device of claim 3, wherein the first contact hole completely surrounds the insulating opening, and the width of the first contact hole ranges from 1.0 micrometer to 1.5 micrometers.

5. The display device of claim 2, wherein the first auxiliary insulating layer comprises a first portion in contact with an upper surface of the first insulating layer and a second portion in contact with a side surface of the first insulating layer, and a thickness of the first portion is greater than a thickness of the second portion.

6. The display device of claim 5, further comprising gate insulating layers located between the semiconductor layer and the first insulating layer, wherein the first auxiliary insulating layer further comprises a third portion in contact with a side surface of at least any one of the gate insulating layers, and the thickness of the second portion of the first auxiliary insulating layer is greater than a thickness of the third portion.

7. The display device of claim 6, wherein the first auxiliary insulating layer further comprises a fourth portion overlapping the contact opening in a direction parallel to a surface of the substrate, and a thickness of the fourth portion is smaller than the thicknesses of the first portion, the second portion and the third portion.

8. The display device of claim 5, wherein the conductive layer covers the upper and side surfaces of the first insulating layer and is spaced apart from the upper and side surfaces of the first insulating layer by the first auxiliary insulating layer located between the conductive layer and the upper and side surfaces of the first insulating layer.

9. The display device of claim 1, wherein the first contact hole has a reverse-tapered shape, and the first insulating layer facing the first contact hole has a tapered shape.

10. The display device of claim 9, wherein an inclination angle formed by a side surface of the first insulating layer which faces the first contact hole and a surface of the substrate is 80 degrees or less.

11. The display device of claim 1, wherein the first auxiliary insulating layer comprises at least any one of silicon nitride and silicon oxynitride.

12. The display device of claim 1, wherein the thickness of the first auxiliary insulating layer is smaller than a thickness of the first insulating layer.

13. The display device of claim 1, further comprising:
a second insulating layer located on the conductive layer;
a second contact hole extending through the second insulating layer to the conductive layer;
a source-drain layer located on the second insulating layer; and
a second auxiliary insulating layer located between the second insulating layer and the source-drain layer and defining an insulating opening,
wherein the insulating opening of the second auxiliary insulating layer overlaps the second contact hole, a width of the insulating opening of the second auxiliary insulating layer is smaller than a width of the second contact hole, and the conductive layer and the source-drain layer contact each other in a portion overlapping the insulating opening of the second auxiliary insulating layer.

14. A method of fabricating a display device, the method comprising:
forming a contact hole which penetrates a plurality of insulating layers;
forming an auxiliary insulating layer which overlaps the contact hole and then forming an insulating opening of the auxiliary insulating layer; and
forming a conductive pattern on the auxiliary insulating layer,
wherein the insulating opening is formed in a portion overlapping the contact hole by performing a dry etching process, a width of the insulating opening is smaller than a width of the contact hole, and the contact hole completely surrounds the insulating opening.

15. The method of claim 14, wherein the auxiliary insulating layer is formed by a sputtering method, and a thickness of the auxiliary insulating layer decreases as a depth of the contact hole increases.

16. An electronic device comprising:
at least one display device comprising a substrate which comprises a semiconductor layer; and
at least any one of a display module, one or more processors, a memory, or a power module connected to the display device,
wherein the at least one display device comprises:
a first insulating layer located on the semiconductor layer;
a first contact hole extending through the first insulating layer to the semiconductor layer;
a conductive layer located on the first insulating layer and contacting the semiconductor layer in a portion overlapping the first contact hole; and
a first auxiliary insulating layer located between the first insulating layer and the conductive layer and defining an insulating opening,
wherein the insulating opening overlaps the first contact hole, a width of the insulating opening is smaller than a width of the first contact hole, and a thickness of the first auxiliary insulating layer decreases in a direction toward the semiconductor layer in the portion overlapping the first contact hole.

17. The electronic device of claim 16, wherein the insulating opening comprises a contact opening, and the semiconductor layer and the conductive layer contact each other in a portion overlapping the contact opening.

18. The electronic device of claim 17, wherein a width of the contact opening is 0.8 micrometers or less.

19. The electronic device of claim 18, wherein the first contact hole completely surrounds the insulating opening.

20. The electronic device of claim 17, wherein the first auxiliary insulating layer comprises a first portion in contact with an upper surface of the first insulating layer and a second portion in contact with a side surface of the first insulating layer, and a thickness of the first portion is greater than a thickness of the second portion.
